(19) United States
(12) Patent Application Publication
(10) Pub. No.: US 2025/0324855 A1
(43) Pub. Date: Oct. 16, 2025

(54) DISPLAY DEVICE

(71) Applicant: Samsung Display Co., LTD., Yongin-si (KR)

(72) Inventors: WOO YONG SUNG, Yongin-si (KR); SEUNGYONG SONG, Yongin-si (KR)

(21) Appl. No.: 19/019,987

(22) Filed: Jan. 14, 2025

(30) Foreign Application Priority Data
Apr. 16, 2024 (KR) 10-2024-0050991

(51) Int. Cl. H10K 59/122; H10H 29/37; H10H 29/85; H10H 29/854; H10K 59/38; H10K 59/80; H10K 59/88

(52) U.S. Cl. CPC H10K 59/122; H10H 29/37; H10H 29/8517; H10H 29/854; H10K 59/38; H10K 59/873; H10K 59/88

(57) ABSTRACT

A display device includes: an insulating layer in which a first groove and a second groove surrounding the first groove are defined; a pixel defining layer disposed on the insulating layer and in which a light emitting opening, a first spacing opening overlapping the first groove, and a second spacing opening overlapping the second groove and surrounding the first spacing opening are defined; a light emitting element including a first electrode of which at least a portion is exposed by the light emitting opening, a second electrode, and a light emitting layer overlapping the light emitting opening; a spacer of which at least a portion is disposed inside the first groove and the first spacing opening; an inorganic encapsulation film disposed on the second electrode and the spacer; and a color filter layer disposed on the inorganic encapsulation film.

This application claims priority to Korean Patent Application No. 10-2024-0050991, filed on Apr. 16, 2024, and all the benefits accruing therefrom under 35 U.S.C. § 119, the content of which in its entirety is herein incorporated by reference.

### BACKGROUND

Embodiments of the present disclosure described herein relate to a display device having improved display quality.

A display device provides information to a user by displaying various images on a display screen. In general, the display device displays information within an allocated screen. The display device may include a display panel, a reflection preventing layer, and a window.

### SUMMARY

Embodiments of the present disclosure provide a display device having improved display quality.

According to an embodiment, a display device includes: an insulating layer in which a first groove and a second groove surrounding the first groove are defined, a pixel defining layer which is disposed on the insulating layer and in which a light emitting opening, a first spacing opening overlapping the first groove, and a second spacing opening overlapping the second groove and surrounding the first spacing opening are defined, a light emitting element disposed on the insulating layer and including a first electrode of which at least a portion is exposed by the light emitting opening, a second electrode disposed on the first electrode, and a light emitting layer disposed between the first electrode and the second electrode and overlapping the light emitting opening, a spacer of which at least a portion is disposed inside the first groove and the first spacing opening, an inorganic encapsulation film disposed on the second electrode and the spacer, and a color filter layer directly disposed on the inorganic encapsulation film.

A first tip portion of the pixel defining layer may protrude from a first inner surface of the insulating layer defining the first groove in a direction toward a center of the first groove.

The spacer may be in contact with the first tip portion.

The spacer may include a first portion disposed inside the first groove and the first spacing opening, and a second portion extending from the first portion and protruding in a direction away from the first spacing opening.

A second tip portion of the pixel defining layer may protrude from a second inner surface of the insulating layer defining the second groove in a direction away from a center of the first groove, and a third tip portion of the pixel defining layer may protrude from a third inner surface of the insulating layer facing and surrounding the second inner surface and defining the second groove in a direction toward the center of the first groove.

The inorganic encapsulation film may be in contact with inner surfaces of the pixel defining layer defining the second spacing opening.

The display device may further include a dummy pattern disposed in the second groove, spaced apart from the second electrode, and including the same material as the second electrode.

The light emitting element may be provided in plurality, and the plurality of light emitting elements may include a first light emitting element in which a first light emitting area that emits a light having a first color is defined, a second light emitting element in which a second light emitting area that emits a light having a second color different from the first color is defined, and a third light emitting element in which a third light emitting area that emits a light having a third color different from the first color and the second color is defined, the light emitting opening may be provided in plurality, and the plurality of light emitting openings may include a first light emitting opening overlapping the first light emitting area, a second light emitting opening overlapping the second light emitting area, and a third light emitting opening overlapping the third light emitting area, and the color filter layer may include a first color filter of which at least a portion overlaps the first light emitting area, a second color filter of which at least a portion overlaps the second light emitting area, and a third color filter of which at least a portion overlaps the third light emitting area.

At least some of the first to third color filters may overlap each other in an area which does not overlap any of the first to third light emitting areas.

Some of the first to third color filters may be arranged inside the second groove and the second spacing opening.

The display device may further include an overcoat layer that covers the color filter layer.

The display device may further include an input sensor layer disposed on the color filter layer.

The input sensor layer may include a first sensing insulating layer disposed on the color filter layer, a second sensing insulating layer disposed on the first sensing insulating layer, a third sensing insulating layer disposed on the second sensing insulating layer, a first conductive layer disposed between the first sensing insulating layer and the second sensing insulating layer, a second conductive layer disposed between the second sensing insulating layer and the third sensing insulating layer, and a light shielding layer that is disposed between the second sensing insulating layer and the third sensing insulating layer and covers the second conductive layer.

The display device may further include a sacrificial pattern which is disposed between the first electrode and the pixel defining layer and in which a sacrificial opening overlapping the light emitting opening is defined.

The inorganic encapsulation film may include a plurality of films.

A third groove surrounding the second groove may be further defined in the insulating layer, and a third spacing opening overlapping the third groove and surrounding the second spacing opening may be further defined in the pixel defining layer.

A fourth tip portion of the pixel defining layer may protrude from a fourth inner surface of the insulating layer defining the third groove in a direction away from a center of the first groove, and a fifth tip portion of the pixel defining layer may protrude from a fifth inner surface of the insulating layer facing and surrounding the fourth inner surface and defining the third groove in a direction toward the center of the first groove.

The display device may further include a first intermediate insulating layer which is disposed between the insulating layer and the pixel defining layer and in which a (1-1)th lower opening overlapping the first groove and a (1-2)^{th} lower opening overlapping the second groove are defined, and a second intermediate insulating layer which is disposed between the first intermediate insulating layer and the pixel defining layer and in which a (2-1)^{th} lower opening overlapping the (1-1)^{th} lower opening and a (2-2)^{th} lower opening overlapping the (1-2)^{th} lower opening are defined, and an inner surface of the second intermediate insulating layer defining the (2-1)^{th} lower opening may be recessed as compared to the first intermediate insulating layer and the pixel defining layer, and an inner surface of the second intermediate insulating layer defining the (2-2)^{th} lower opening may be recessed as compared to the first intermediate insulating layer and the pixel defining layer.

According to an embodiment, an electronic device includes: an insulating layer in which a first groove and a second groove surrounding the first groove are defined, a pixel defining layer disposed on the insulating layer and including a first tip portion protruding from an inner edge of the insulating layer defining the first groove and second and third tip portions protruding from inner edges of the insulating layer defining the second groove, a light emitting element disposed on the insulating layer, a spacer of which at least a portion is disposed inside the first groove, an inorganic encapsulation film disposed on a second electrode and the spacer, and a color filter layer directly disposed on the inorganic encapsulation film.

The inorganic encapsulation film may be in contact with the second and third tip portions.

### BRIEF DESCRIPTION OF THE FIGURES

The above and other aspects and features of the present disclosure will become apparent by describing in detail embodiments thereof with reference to the accompanying drawings.

FIG. 1 is a perspective view of a display device according to an embodiment of the present disclosure.

FIG. 2 is a schematic cross-sectional view of the display device according to an embodiment of the present disclosure.

FIG. 3 is an enlarged plan view illustrating a partial area of a display layer according to an embodiment of the present disclosure.

FIG. 4 is a cross-sectional view of a display panel according to an embodiment of the present disclosure.

FIG. 5 is a cross-sectional view of the display panel according to an embodiment of the present disclosure.

FIG. 6A is a cross-sectional view of the display panel according to an embodiment of the present disclosure.

FIG. 6B is an enlarged plan view illustrating some components of the display panel according to an embodiment of the present disclosure.

FIG. 6C is an enlarged cross-sectional view illustrating area AA′ of FIG. 6A.

FIG. 6D is an enlarged cross-sectional view illustrating area BB′ of FIG. 6A.

FIG. 7 is a cross-sectional view of the display panel according to an embodiment of the present disclosure.

FIG. 8A is a cross-sectional view of the display panel according to an embodiment of the present disclosure.

FIG. 8B is an enlarged plan view illustrating a partial configuration of the display panel according to an embodiment of the present disclosure.

FIG. 9 is an enlarged cross-sectional view illustrating a partial area of the display panel according to an embodiment of the present disclosure.

FIGS. 10A to 10G are cross-sectional views illustrating some of operations of a method of manufacturing the display panel according to an embodiment of the present disclosure.

### DETAILED DESCRIPTION

In the specification, the expression that a first component (or an area, a layer, a part, a portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and the dimension of components are exaggerated for effective description of technical contents. The term “and/or” includes all combinations of one or more components that may be defined by associated components.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

Hereinafter, an embodiment of the present disclosure will be described with reference to the accompanying drawings.

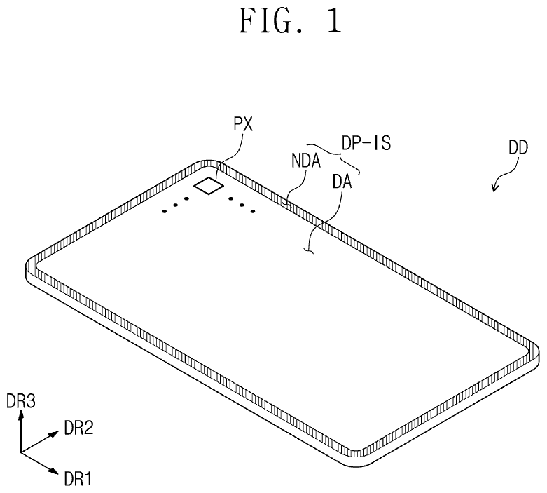

FIG. 1 is a perspective view of a display device DD according to an embodiment of the present disclosure.

In an embodiment, the display device DD may be a large electronic device such as a television, a monitor, or an external billboard. Further, the display device DD may be a small or medium-sized electronic device such as a personal computer (“PC”), a laptop, a personal digital terminal, a vehicle navigation unit, a game console, a smart phone, a tablet PC, and a camera. However, this is illustrative, and other display devices may be adopted as long as the display devices do not deviate from the concept of the present disclosure.

Referring to FIG. 1, the display device DD may display an image in a third direction DR3 on a display surface DP-IS parallel to a first direction DR1 and a second direction DR2. The image may include a still image as well as a dynamic image. The display surface DP-IS on which the image is displayed may correspond to a front surface of the display device DD.

In an embodiment, a front surface (or an upper surface) and a rear surface (or a lower surface) of each member are defined with respect to a direction in which the image is displayed. The front surface and the rear surface may face each other in the third direction DR3, and a normal direction of each of the front surface and the rear surface may be parallel to the third direction DR3. Meanwhile, directions indicated by the first to third directions DR1, DR2, and DR3 are relative concepts and may be changed to other directions. In the specification, a phrase of “on a plane” (in other words, “in a plan view”) may mean a state when viewed in the third direction DR3 (i.e., thickness direction of the display device DD).

The display device DD may include a display area DA and a non-display area NDA. Pixels PX are arranged in the display area DA, and the pixels PX are not arranged in the non-display area NDA. The non-display area NDA is defined along an edge of the display surface DP-IS. The non-display area NDA may surround the display area DA in a plan view. However, this is illustrative, and the present disclosure is not limited thereto. For example, in another embodiment of the present disclosure, the non-display area NDA may be omitted or disposed on only one side of the display area DA. Further, FIG. 1 illustratively illustrates the planar display device DD, but the display device DD may have a curved shape.

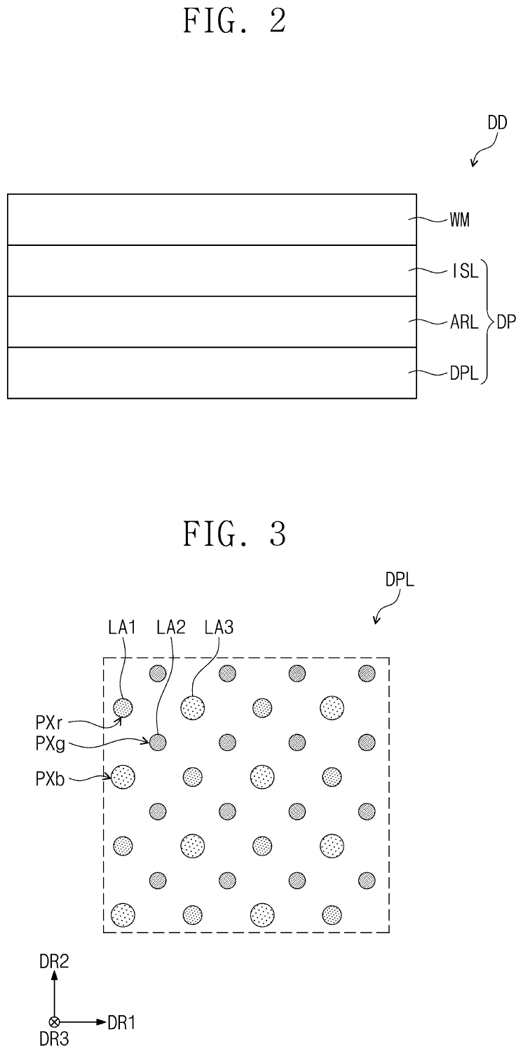

FIG. 2 is a schematic cross-sectional view of the display device DD according to an embodiment of the present disclosure.

Referring to FIG. 2, the display device DD may include a display panel DP and a window WM. The display panel DP may include a display layer DPL, a reflection preventing layer ARL, and an input sensor layer ISL.

The display layer DPL may be a light emitting display layer. For example, the display layer DPL may be an organic light emitting display layer, an inorganic light emitting display layer, an organic-inorganic light emitting display layer, a micro-light emitting diode (“LED”) display layer, or a nano-LED display layer.

The reflection preventing layer ARL may be disposed on the display layer DPL. The reflection preventing layer ARL may reduce reflectance of an external light.

The reflection preventing layer ARL may be disposed on the display layer DPL through a continuous process. In this case, the reflection preventing layer ARL may be directly disposed on the display layer DPL. In the specification, the wording “component ‘B’ is directly disposed on component ‘A’” may mean that no third component is disposed between component ‘A’ and component ‘B’. For example, no adhesive layer may be disposed between the reflection preventing layer ARL and the display layer DPL.

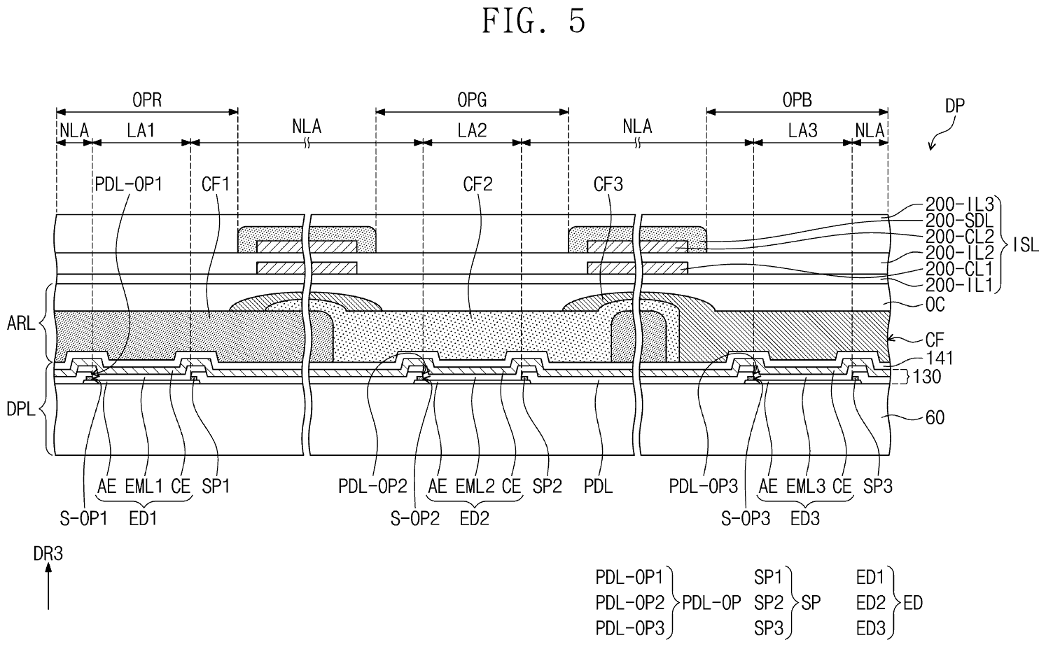

The reflection preventing layer ARL may include a color filter layer CF (see FIG. 5), which will be described below. The color filter layer CF may include a plurality of color filters CF1, CF2, and CF3 (see FIG. 5). A detailed description of the reflection preventing layer ARL will be made below.

The input sensor layer ISL may be disposed on the reflection preventing layer ARL. The input sensor layer ISL may sense an external input applied from an external unit. The external input may be input of the user. The input of the user may include various types of external inputs such as a portion of the body of the user, light, heat, a pen, and pressure.

The input sensor layer ISL may be formed on the reflection preventing layer ARL through a continuous process. In this case, the input sensor layer ISL may be directly disposed on the reflection preventing layer ARL.

The window WM may be disposed on the input sensor layer ISL. The window WM and the input sensor layer ISL may be coupled to each other by an adhesive layer. The adhesive layer may be a pressure sensitive adhesive (“PSA”) film or an optically clear adhesive (“OCA”) member.

The window WM includes at least one base layer 110. The base layer 110 may be a glass substrate or a synthetic resin film. The window WM may have a multi-layer structure. The window WM may include a thin film glass substrate and a synthetic resin film disposed on the thin film glass substrate. The thin film glass substrate and the synthetic resin film may be coupled to each other by an adhesive layer, and the adhesive layer and the synthetic resin film may be separated from the thin film glass substrate for the purpose of replacement thereof.

In an embodiment of the present disclosure, the adhesive layer may be omitted, and the window WM may be directly disposed on the input sensor layer ISL. Organic materials, inorganic materials, or ceramic materials may be coated on the input sensor layer ISL.

FIG. 3 is an enlarged plan view illustrating a partial area of the display layer DPL according to an embodiment of the present disclosure.

Referring to FIG. 3, the display layer DPL may include a plurality of pixels PXr, PXg, and PXb. The pixels PXr, PXg, and PXb may include the first pixel PXr, the second pixel PXg, and the third pixel PXb.

A first light emitting area LA1 may be defined in the first pixel PXr, a second light emitting area LA2 may be defined in the second pixel PXg, and a third light emitting area LA3 may be defined in the third pixel PXb. Circular shapes illustrated in FIG. 3 may correspond to shapes of the first to third light emitting areas LA1, LA2, and LA3, respectively. However, the shapes of the first to third light emitting areas LA1, LA2, and LA3 are not limited thereto. For example, the first to third light emitting areas LA1, LA2, and LA3 may have various shapes, such as a quadrangular shape, a polygonal shape, an elliptical shape, a triangular shape, or an irregular shape, on a plane.

In an embodiment of the present disclosure, the first pixel PXr and the third pixel PXb may be alternately and repeatedly arranged one by one in the first direction DR1 and the second direction DR2. The second pixel PXg may be disposed in a space between two first pixels PXr adjacent to each other in a diagonal direction and two third pixels PXb adjacent to each other in the diagonal direction. However, the arrangement relationship between the first to third pixels PXr, PXg, and PXb as illustrated in FIG. 3 is an example, and the arrangement relationship between the first to third pixels PXr, PXg, and PXb is not particularly limited thereto. The diagonal direction may be a direction between the first direction DR1 and the second direction DR2 or a direction between a direction opposite to the first direction DR1 and the second direction DR2.

In an embodiment of the present disclosure, an area of the third light emitting area LA3 may be largest, and an area of the second light emitting area LA2 may be smallest. However, the present disclosure is not particularly limited thereto. For example, areas of the first to third light emitting areas LA1, LA2, and LA3 may be the same or may be different from the illustrated example.

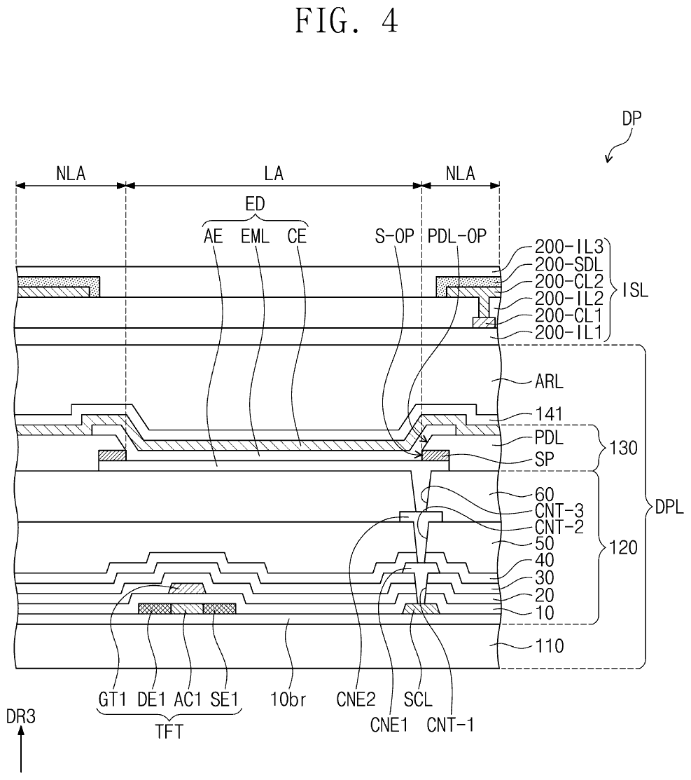

FIG. 4 is a cross-sectional view of the display panel DP according to an embodiment of the present disclosure.

FIG. 4 illustrates a cross section corresponding to one light emitting area LA and a non-light emitting area NLA surrounding the light emitting area LA in a plan view and illustratively illustrates one pixel disposed on the one light emitting area LA. One pixel illustrated in FIG. 4 may correspond to any one of the first to third pixels PXr, PXg, and PXb described above with reference to FIG. 3. The pixel may include a light emitting element ED and a driving circuit of the pixel, which is electrically connected to the light emitting element ED. FIG. 4 illustrates the light emitting element ED and a transistor TFT connected thereto. The transistor TFT may be one of a plurality of transistors TFT included in the driving circuit of the pixel. In an embodiment, the transistor TFT may be described as a silicon transistor but may be a metal oxide transistor.

Referring to FIG. 4, the display panel DP may include the display layer DPL, the reflection preventing layer ARL, and the input sensor layer ISL. The display layer DPL may include the base layer 110, a circuit layer 120, a light emitting element layer 130, and an inorganic encapsulation film 141.

The base layer 110 may provide a base surface on which the circuit layer 120 is disposed. The base layer 110 may be a rigid substrate or a flexible substrate that may be bent, folded, and rolled. The base layer 110 may be a glass substrate, a metal substrate, a polymer substrate, or the like. However, an embodiment of the present disclosure is not limited thereto, and the base layer 110 may include an inorganic layer, an organic layer, or a composite material layer in another embodiment.

The base layer 110 may have a multi-layer structure. For example, the base layer 110 may include a first synthetic resin layer, a multi-layer or single-layer inorganic layer, and a second synthetic resin layer disposed on the multi-layer or single-layer inorganic layer. Each of the first and second synthetic resin layers may include a polyimide-based resin, but the present disclosure is not particularly limited thereto.

The circuit layer 120 may be disposed on the base layer 110. The circuit layer 120 may include an insulating layer, a semiconductor pattern, a conductive pattern, a signal line, and a driving circuit for the pixel PX. For example, the circuit layer 120 may include a buffer layer 10br, first to sixth insulating layers 10, 20, 30, 40, 50, and 60, a signal transmitting area SCL, and a plurality of connection electrodes CNE1 and CNE2.

The buffer layer 10br may be disposed on the base layer 110. The buffer layer 10br may prevent metal atoms or impurities from being diffused from the base layer 110 to an upper semiconductor pattern. The semiconductor pattern includes an active area AC1 of the transistor TFT. A rear metal layer may be additionally disposed between the base layer 110 and the buffer layer 10br. The rear metal layer may be disposed under the transistor TFT and may prevent an external light from reaching the transistor TFT.

The semiconductor pattern may be disposed on the buffer layer 10br. The semiconductor pattern may include a silicon semiconductor. For example, the silicon semiconductor may include amorphous silicon, polycrystalline silicon, and/or the like. For example, the semiconductor pattern may include a low temperature polysilicon.

The semiconductor pattern may include a first area having higher conductivity and a second area having lower conductivity. The first area may be doped with an N-type dopant or a P-type dopant. A P-type transistor TFT may include a doped area doped with a P-type dopant, and an N-type transistor TFT may include a doped area doped with an N-type dopant. The second area may be a non-doped area or may be an area doped at a concentration that is lower than a concentration of the first area.

A conductivity of the first area is greater than a conductivity of the second area, and the first area may substantially serve as an electrode or a signal line. The second area may substantially correspond to the active area AC1 (or a channel) of the transistor TFT. In other words, a portion of the semiconductor pattern may be the active area AC1 of the transistor TFT, another portion thereof may be a source or drain of the transistor TFT, and still another portion thereof may be a connection electrode or a connection signal line.

The transistor TFT may include a source area SE1 (or a source), the active area AC1 (or a channel), a drain area DE1 (or a drain), and a gate GT1. The source area SE1, the active area AC1, and the drain area DE1 of the transistor TFT may be formed from the semiconductor pattern. The source area SE1 and the drain area DE1 may extend from the active area AC1 in opposite directions on a cross sectional view. FIG. 4 illustrates a portion of the signal transmitting area SCL formed from the semiconductor pattern. Although not separately illustrated, the signal transmitting area SCL may be connected to the drain area DE1 of the transistor TFT on a plane (i.e., in a plan view).

The first insulating layer 10 may be disposed on the buffer layer 10br. The first insulating layer 10 may cover the source area SE1, the active area AC1, and the drain area DE1 of the transistor TFT disposed on the buffer layer 10br, and the signal transmitting area SCL disposed on the buffer layer 10br.

The first insulating layer 10 may include an inorganic layer and/or an organic layer and may have a single-layer structure or a multi-layer structure. The inorganic layer may include at least one of an aluminum oxide, a titanium oxide, a silicon oxide, a silicon nitride, a silicon oxy nitride, a zirconium oxide, or a hafnium oxide. In an embodiment, the first insulating layer 10 may be a single-layered silicon oxide layer. The first insulating layer 10 and an insulating layer of the circuit layer 120, which will be described below, may be an inorganic layer and/or an organic layer, and may have a single-layer structure or a multi-layer structure. The inorganic layer may include at least one of the above-described materials, but the present disclosure is not limited thereto.

The gate GT1 of the transistor TFT may be disposed on the first insulating layer 10. The gate GT1 may be a portion of a metal pattern. The gate GT1 may overlap the active area AC1. The gate GT1 may function as a mask in a process of doping the semiconductor pattern. The gate GT1 may include titanium (Ti), silver (Ag), an alloy containing silver, molybdenum (Mo), an alloy containing molybdenum, aluminum (Al), an alloy containing aluminum, aluminum nitride (“AlN”), tungsten (W), tungsten nitride (WN), copper (Cu), indium tin oxide (“ITO”), indium zinc oxide (“IZO”) or the like, but the present disclosure is not particularly limited thereto.

The second insulating layer 20 may be disposed on the first insulating layer 10 to cover the gate GT1. The third insulating layer 30 may be disposed on the second insulating layer 20.

The first connection electrode CNE1 may be disposed on the third insulating layer 30. The first connection electrode CNE1 may be connected to the signal transmitting area SCL through a contact hole CNT-1 passing through the first to third insulating layers 10, 20, and 30. The fourth insulating layer 40 may be disposed on the third insulating layer 30 to cover the first connection electrode CNE1. The fourth insulating layer 40 may be an organic layer.

The fifth insulating layer 50 may be disposed on the fourth insulating layer 40. The second connection electrode CNE2 may be disposed on the fifth insulating layer 50. The second connection electrode CNE2 may be connected to the first connection electrode CNE1 through a contact hole CNT-2 passing through the fourth insulating layer 40 and the fifth insulating layer 50. The fifth insulating layer 50 may be an organic layer.

The sixth insulating layer 60 may be disposed on the fifth insulating layer 50 to cover the second connection electrode CNE2. The sixth insulating layer 60 may be an organic layer. A laminated structure of the first to sixth insulating layers 10, 20, 30, 40, 50, and 60 is merely an example, and additional conductive layers and additional insulating layers in addition to the first to sixth insulating layers 10, 20, 30, 40, 50, and 60 may be further arranged.

The light emitting element layer 130 may be disposed on the circuit layer 120. The light emitting element layer 130 may include the light emitting element ED and a pixel defining layer PDL.

The light emitting element ED may include an organic light emitting element, an inorganic light emitting element, an organic-inorganic light emitting element, a quantum dot light emitting element, a micro LED light emitting element, or a nano LED light emitting element. However, an embodiment is not limited thereto, and the light emitting element ED may include an embodiment as long as a light may be generated or the quantity of light may be controlled according to an electrical signal.

The light emitting element ED may include a first electrode AE (or an anode), a light emitting layer EML, and a second electrode CE (or a cathode). The second electrode CE may be disposed on the first electrode AE, and the light emitting layer EML may be disposed between the first electrode AE and the second electrode CE. The first electrode AE may be disposed on the sixth insulating layer 60. The first electrode AE may be a transmissive electrode, a semi-transmissive electrode, or a reflective electrode. The first electrode AE may include a reflective layer formed of Ag, Mg, Al, Pt, Pd, Au, Ni, Nd, Ir, Cr or a compound thereof, and a transparent or semitransparent electrode layer disposed on the reflective layer. The transparent or semitransparent electrode layer may include at least one selected from the group consisting of an indium tin oxide (ITO), an indium zinc oxide (IZO), an indium gallium zinc oxide (“IGZO”), a zinc oxide (ZnO) or an indium oxide (In₂O₃), and an aluminum-doped zinc oxide (“AZO”). For example, the first electrode AE may include a laminated structure of ITO/Ag/ITO.

According to an embodiment of the present disclosure, the display panel DP may further include a sacrificial pattern SP. The sacrificial pattern SP may be disposed between the first electrode AE and the pixel defining layer PDL. A sacrificial opening S-OP, through which a portion of an upper surface of the first electrode AE is exposed, may be defined in the sacrificial pattern SP. The sacrificial pattern SP may include an amorphous transparent conductive oxide.

The pixel defining layer PDL may be disposed on the sixth insulating layer 60. The pixel defining layer PDL may cover a portion of the first electrode AE. For example, a light emitting opening PDL-OP, through which a portion of the first electrode AE is exposed, may be defined in the pixel defining layer PDL. The light emitting opening PDL-OP of the pixel defining layer PDL may define the light emitting area LA. That is, the light emitting area LA may be defined to correspond to a partial area of the first electrode AE exposed from the pixel defining layer PDL by the light emitting opening PDL-OP.

The light emitting opening PDL-OP may overlap the sacrificial opening S-OP of the sacrificial pattern SP in a plan view. According to an embodiment, the upper surface of the first electrode AE may be spaced apart from the pixel defining layer PDL On a cross sectional view with the sacrificial pattern SP interposed therebetween, and accordingly, damage to the first electrode AE may be prevented in a process of forming the light emitting opening PDL-OP.

FIG. 4 illustratively illustrates that an area of the sacrificial opening S-OP and an area of the light emitting opening PDL-OP are substantially the same. However, an embodiment is not limited thereto, and the area of the light emitting opening PDL-OP may be smaller than the area of the sacrificial opening S-OP, and an inner surface of the pixel defining layer PDL that defines the light emitting opening PDL-OP may be closer to a center of the first electrode AE than an inner surface of the sacrificial pattern SP that defines the sacrificial opening S-OP. In another embodiment of the present disclosure, the sacrificial pattern SP may be omitted.

The pixel defining layer PDL may include an inorganic insulating material. For example, the pixel defining layer PDL may include a silicon nitride (SiNₓ).

According to an embodiment, the pixel defining layer PDL may have a property of absorbing a light, and for example, the pixel defining layer PDL may have a black color. The pixel defining layer PDL may include a black coloring agent. The black coloring agent may include black dye and black pigment. The black coloring agent may include carbon black, a metal such as chromium, or an oxide thereof. The pixel defining layer PDL may correspond to a light shielding pattern having light shielding characteristics.

A hole control layer may be further disposed between the first electrode AE and the light emitting layer EML. The hole control layer may further include a hole transport layer and/or a hole injection layer. An electron control layer may be further disposed between the light emitting layer EML and the second electrode CE. The electron control layer may further include an electron transport layer and/or an electron injection layer.

Although not illustrated, in an embodiment of the present disclosure, the light emitting element layer 130 may further include a capping layer. The capping layer may be disposed on the light emitting element ED and cover the second electrode CE of the light emitting element ED. The capping layer may include an organic material. The capping layer may be formed as a single layer or multiple layers. The capping layer may sufficiently protect a lower negative electrode and an organic light emitting layer from moisture penetration or contamination from the outside, and accordingly, the light emitting element ED having improved lifetime may be provided.

The inorganic encapsulation film 141 may be disposed on the light emitting element layer 130. The inorganic encapsulation film 141 may protect the light emitting element layer 130 from foreign substances such as moisture, oxygen, and dust particles. The inorganic encapsulation film 141 may have a single-layer structure or have a multi-layer structure in which layers are laminated in the third direction DR3. In other words, the inorganic encapsulation film 141 may be formed as a single-layer inorganic film or may have a structure in which multi-layer inorganic films are laminated. The inorganic encapsulation film 141 may protect the light emitting element layer 130 from moisture and oxygen. The inorganic encapsulation film 141 may include a silicon nitride layer, a silicon oxy nitride layer, a silicon oxide layer, a titanium oxide layer, an aluminum oxide layer, or the like.

The reflection preventing layer ARL may be disposed on the display layer DPL. In an embodiment, an organic film that may protect the light emitting element layer 130 from foreign substances through the reflection preventing layer ARL and provide a flat surface to the input sensor layer ISL may be provided. A detailed description thereof will be made below.

The input sensor layer ISL may be disposed on the reflection preventing layer ARL. The input sensor layer ISL may be referred to as a sensor layer, an input sensor layer, or an input sensing panel. The input sensor layer ISL may include a first sensing insulating layer 200-IL1, a first conductive layer 200-CL1, a second sensing insulating layer 200-IL2, a second conductive layer 200-CL2, and a third sensing insulating layer 200-IL3.

The first sensing insulating layer 200-IL1 may be directly disposed on the display layer DPL. The first sensing insulating layer 200-IL1 may be an inorganic layer including at least one of silicon nitride, silicon oxy nitride, or silicon oxide. Alternatively, the first sensing insulating layer 200-IL1 may be an organic layer including an epoxy resin, an acrylic resin, or an imide-based resin. The first sensing insulating layer 200-IL1 may have a single-layer structure or have a multi-layer structure in which layers are laminated in the third direction DR3.

Each of the first conductive layer 200-CL1 and the second conductive layer 200-CL2 may have a single-layer structure or have a multi-layer structure in which layers are laminated in the third direction DR3. Each of the first conductive layer 200-CL1 and the second conductive layer 200-CL2 may include a mesh-shaped sensing pattern or bridge pattern.

The conductive layer having a single-layer structure may include a metal layer or a transparent conductive layer. The metal layer may include molybdenum, silver, titanium, copper, aluminum, or alloys thereof. The transparent conductive layer may include a transparent conductive oxide such as an indium tin oxide (ITO), an indium zinc oxide (IZO), or an indium zinc tin oxide (IZTO). In addition, the transparent conductive layer may include a conductive polymer such as poly(3,4-ethylenedioxythiophene) (“PEDOT”), metal nanowire, graphene, or the like.

The conductive layer having a multi-layer structure may include metal layers. The metal layers may have, for example, a three-layer structure of titanium/aluminum/titanium. The conductive layer having a multi-layer structure may include at least one metal layer and at least one transparent conductive layer.

The second sensing insulating layer 200-IL2 may be disposed between the first conductive layer 200-CL1 and the second conductive layer 200-CL2. The third sensing insulating layer 200-IL3 may be disposed on the second sensing insulating layer 200-IL2 and cover the second conductive layer 200-CL2. The third sensing insulating layer 200-IL3 may reduce or remove a probability that the second conductive layer 200-CL2 is damaged in a subsequent process. In an embodiment of the present disclosure, the input sensor layer ISL may not include the third sensing insulating layer 200-IL3.

The second sensing insulating layer 200-IL2 and the third sensing insulating layer 200-IL3 may include an inorganic layer. The inorganic film may include at least one of an aluminum oxide, a titanium oxide, a silicon oxide, a silicon nitride, a silicon oxy nitride, a zirconium oxide, or a hafnium oxide.

Alternatively, the second sensing insulating layer 200-IL2 and the third sensing insulating layer 200-IL3 may include at least one of an epoxy-based resin, an urethane-based resin, a cellulose-based resin, a siloxane-based resin, a polyimide-based resin, a polyamide-based resin, or a perylene-based resin.

The input sensor layer ISL according to an embodiment of the present disclosure may further include a light shielding layer 200-SDL. The light shielding layer 200-SDL may be disposed between the second sensing insulating layer 200-IL2 and the third sensing insulating layer 200-IL3 and cover the second conductive layer 200-CL2. For example, the light shielding layer 200-SDL may cover all an upper surface and side surfaces of a sensing pattern and/or a bridge pattern included in the second conductive layer 200-CL2.

The light shielding layer 200-SDL may have a black color pattern, and in an embodiment, the light shielding layer 200-SDL may include a black coloring agent. The black coloring agent may include black dye and black pigment. The black coloring agent may include carbon black, a metal such as chromium, or an oxide thereof. However, this is illustrative, and a material constituting the light shielding layer 200-SDL is not particularly limited as long as the material absorbs a light.

FIG. 5 is a cross-sectional view of the display panel DP according to an embodiment of the present disclosure.

In description of FIG. 5, the description will be made with reference to FIG. 4, and descriptions for the same reference numerals will be omitted. A description of each of first to third light emitting elements ED1, ED2, and ED3 of FIG. 5 may be substantially the same as the description of the light emitting element ED of FIG. 4.

Referring to FIG. 5, the display panel DP may include the sixth insulating layer 60, the light emitting element layer 130, the inorganic encapsulation film 141, and the input sensor layer ISL. In FIG. 5, for convenience of description, the circuit layer 120 (see FIG. 4) and the base layer 110 (see FIG. 4) except for the sixth insulating layer 60 are omitted. That is, FIG. 5 illustrates only an insulating layer (i.e., the sixth insulating layer 60) disposed on an uppermost side of the circuit layer 120 (see FIG. 4).

The light emitting element ED may be provided as a plurality of light emitting elements ED. The plurality of light emitting elements ED may include the first light emitting element ED1, the second light emitting element ED2, and the third light emitting element ED3. The first light emitting area LA1 that emits a light having a first color may be defined in the first light emitting element ED1. The second light emitting area LA2 that emits a light having a second color different from the first color may be defined in the second light emitting element ED2. The third light emitting area LA3 that emits a light having a third color different from the first and second colors may be defined in the third light emitting element ED3. The first light emitting element ED1 may correspond to the light emitting element ED included in the first pixel PXr described above with reference to FIG. 3, the second light emitting element ED2 may correspond to the light emitting element ED included in the second pixel PXg described above with reference to FIG. 3, and the third light emitting element ED3 may correspond to the light emitting element ED included in the third pixel PXb described above with reference to FIG. 3.

The first light emitting element ED1 may include the first electrode AE, a first light emitting layer EML1, and the second electrode CE. The second light emitting element ED2 may include the first electrode AE, a second light emitting layer EML2, and the second electrode CE. The third light emitting element ED3 may include the first electrode AE, a third light emitting layer EML3, and the second electrode CE.

In an embodiment, the first electrodes of the first to third light emitting elements ED1, ED2, and ED3 may be provided as a plurality of patterns.

The light emitting opening PDL-OP may be defined in the pixel defining layer PDL. The light emitting opening PDL-OP may be provided as a plurality of light emitting openings PDL-OP. The plurality of light emitting openings PDL-OP may include a first light emitting opening PDL-OP1 that overlaps the first light emitting area LA1 (or defines the first light emitting area LA1), a second light emitting opening PDL-OP2 that overlaps the second light emitting area LA2 (or defines the second light emitting area LA2), and a third light emitting opening PDL-OP3 that overlaps the third light emitting area LA3 (or defines the third light emitting area LA3). The first light emitting opening PDL-OP1 may expose at least a portion of the first electrode AE of the first light emitting element ED1. The second light emitting opening PDL-OP2 may expose at least a portion of the first electrode AE of the second light emitting element ED2. The third light emitting opening PDL-OP3 may expose at least a portion of the first electrode AE of the third light emitting element ED3.

The first to third light emitting layers EML1, EML2, and EML3 may be arranged on the first electrode AE and the pixel defining layer PDL. The first to third light emitting layers EML1, EML2, and EML3 may be arranged in the first to third light emitting openings PDL-OP1, PDL-OP2, and PDL-OP3, respectively. The first light emitting layer EML1 may overlap the first light emitting opening PDL-OP1 in a plan view and may be disposed on the first electrode AE of the first light emitting element ED1. The second light emitting layer EML2 may overlap the second light emitting opening PDL-OP2 in a plan view and may be disposed on the first electrode AE of the second light emitting element ED2. The third light emitting layer EML3 may overlap the third light emitting opening PDL-OP3 in a plan view and may be disposed on the first electrode AE of the third light emitting element ED3.

The second electrode CE may be disposed on the first to third light emitting layers EML1, EML2, and EML3 and the pixel defining layer PDL. The second electrode CE may overlap the first to third light emitting openings PDL-OP1, PDL-OP2, and PDL-OP3 in a plan view. The second electrode CE of the first light emitting element ED1 may overlap the first light emitting opening PDL-OP1 in a plan view and may be disposed on the first light emitting layer EML1. The second electrode CE of the second light emitting element ED2 may overlap the second light emitting opening PDL-OP2 in a plan view and may be disposed on the second light emitting layer EML2. The second electrode CE of the third light emitting element ED3 may overlap the third light emitting opening PDL-OP3 in a plan view and may be disposed on the third light emitting layer EML3. In an embodiment, the second electrodes CE of the first to third light emitting elements ED1, ED2, and ED3 may be formed as a common layer and provided as an integrated electrode.

FIG. 5 illustratively illustrates that the first to third light emitting layers EML1, EML2, and EML3 are arranged on the first electrodes AE of the first to third light emitting elements ED1, ED2, and ED3 and the pixel defining layer PDL, but the present disclosure is not limited thereto. For another example, the first to third light emitting layers EML1, EML2, and EML3 may be arranged only on the first electrodes AE of the first to third light emitting elements ED1, ED2, and ED3.

The first to third light emitting layers EML1, EML2, and EML3 may provide lights having different colors. For example, the first light emitting layer EML1 may provide a red light, the second light emitting layer EML2 may provide a green light, and the third light emitting layer EML3 may provide a blue light.

The sacrificial pattern SP may include a first sacrificial pattern SP1, a second sacrificial pattern SP2, and a third sacrificial pattern SP3. Each of the first to third sacrificial patterns SP1, SP2, and SP3 may be disposed on an upper surface of the corresponding first electrode AE. First to third sacrificial openings S-OP1, S-OP2, and S-OP3 overlapping to the first to third light emitting openings PDL-OP1, PDL-OP2, and PDL-OP3 in a plan view may be defined in the first to third sacrificial patterns SP1, SP2, and SP3, respectively.

The reflection preventing layer ARL may include the color filter layer CF and an overcoat layer OC. The color filter layer CF may be directly disposed on the inorganic encapsulation film 141, and the overcoat layer OC may be directly disposed on the color filter layer CF.

The color filter layer CF may include a first color filter CF1, a second color filter CF2, and a third color filter CF3. At least a portion of the first color filter CF1 may overlap the first light emitting area LA1. At least a portion of the second color filter CF2 may overlap the second light emitting area LA2. At least a portion of the third color filter CF3 may overlap the third light emitting area LA3.

The first to third color filters CF1, CF2, and CF3 may correspond to the first to third light emitting elements ED1, ED2, and ED3, may transmit lights generated by the first to third light emitting elements ED1, ED2, and ED3, and may shield lights having some wavelength bands among an external light. The first color filter CF1 may transmit the light having the first color, the second color filter CF2 may transmit the light having the second color, and the third color filter CF3 may transmit the light having the third color. The second color may be different from the first color, and the third color may be different from the first and second colors. For example, the first color may be red, the second color may be green, and the third color may be blue.

Each of the first to third color filters CF1, CF2, and CF3 may include a polymer photosensitive resin and a colorant. In the specification, the colorant includes a pigment and a dye. A red colorant may include a red pigment and a red dye, a green colorant may include a green pigment and a green dye, and a blue colorant may include a blue pigment and a blue dye.

For example, the first color filter CF1 may include a red pigment or a red dye, the second color filter CF2 may include a green pigment or a green dye, and the third color filter CF3 may include a blue pigment or a blue dye. Among lights provided from the light emitting element layer 130, a light passing through the first color filter CF1 may provide a red light to the outside of the display panel DP, a light passing through the second color filter CF2 may provide a green light to the outside of the display panel DP, and a light passing through the third color filter CF3 may provide a blue light to the outside of the display panel DP.

According to an embodiment, the color filters CF1, CF2, and CF3 are directly arranged on the display layer DPL, and thus the color filter layer CF may cover the second electrode CE of the first light emitting element ED1, the second electrode CE of the second light emitting element ED2, and the second electrode CE of the third light emitting element ED3. Accordingly, reflection of an external light, which is caused by the electrodes (e.g., the first electrodes AE and the second electrodes CE of the first to third light emitting elements ED1, ED2, and ED3) inside the display layer DPL, may be effectively reduced or prevented.

In an embodiment of the present disclosure, at least some of the first to third color filters CF1, CF2, and CF3 may overlap each other in areas that do not overlap any of the first to third light emitting areas LA1, LA2, and LA3. That is, at least some of the first to third color filters CF1, CF2, and CF3 may be arranged in a laminated form in the third direction DR3 in areas that overlap the non-light emitting area NLA. The first to third color filters CF1, CF2, and CF3 that overlap each other in a thickness direction (i.e., the third direction DR3) may shield the light passing through the non-light emitting area NLA to prevent color mixing between the first to third light emitting areas LA1, LA2, and LA3. For example, the first color filter CF1 may include openings corresponding to the second and third light emitting areas LA2 and LA3 and may be disposed to overlap the first light emitting area LA1 and the non-light emitting area NLA. The second color filter CF2 may include openings corresponding to the first and third light emitting areas LA1 and LA3 and may be disposed to overlap the second light emitting area LA2 and the non-light emitting area NLA. The third color filter CF3 may include openings corresponding to the first and second light emitting areas LA1 and LA2 and may be disposed to overlap the third light emitting area LA3 and the non-light emitting area NLA.

However, an embodiment is not limited thereto, and the first to third color filters CF1, CF2, and CF3 may not overlap each other in the thickness direction (i.e., third direction DR3) in another embodiment. For example, the first to third color filters CF1, CF2, and CF3 may be arranged in pattern forms corresponding to the first to third light emitting elements ED1, ED2, and ED3, respectively. Alternatively, only two of the first to third color filters CF1, CF2, and CF3 may overlap each other in the thickness direction. For example, the first and second color filters CF1 and CF2 may be arranged in pattern forms corresponding to the first and second light emitting areas LA1 and LA2, and the third color filter CF3 may include the openings corresponding to the first and second light emitting areas LA1 and LA2 and may be arranged to overlap the third light emitting area LA3 and the non-light emitting area NLA.

The overcoat layer OC may cover the color filter layer CF. The overcoat layer OC may cover the first color filter CF1, the second color filter CF2, and the third color filter CF3. The overcoat layer OC may contain an organic material and provide a flat upper surface. The organic material may be transparent and may include, for example, an acrylic-based resin. According to an embodiment, the overcoat layer OC may protect the light emitting element layer 130 from foreign substances such as dust particles.

In an embodiment, the overcoat layer OC may be formed through a coating or deposition process. In more detail, the overcoat layer OC may be formed by forming an organic layer by manners such as coating and deposition and then selectively patterning the organic layer by photolithography and etching. In this case, as compared to a case in which the organic layer is formed by an inkjet process, a higher flattening level may be maintained at an edge thereof, and a more decreased thickness may be provided. Accordingly, a distance between the light emitting element ED and the light shielding layer 200-SDL may be effectively decreased, and a viewing angle may be effectively widened.

The input sensor layer ISL may be disposed on the reflection preventing layer ARL. In an embodiment, the input sensor layer ISL may include the first sensing insulating layer 200-IL1, the first conductive layer 200-CL1, the second sensing insulating layer 200-IL2, the second conductive layer 200-CL2, the light shielding layer 200-SDL, and the third sensing insulating layer 200-IL3.

A plurality of openings OPR, OPG, and OPB may be defined in the light shielding layer 200-SDL. The openings OPR, OPG, and OPB may overlap the first to third light emitting layers EML1, EML2, and EML3, respectively, and may be referred to as the first to third openings OPR, OPG, and OPB. The first to third color filters CF1, CF2, and CF3 may be arranged to correspond to the first to third openings OPR, OPG, and OPB, respectively. Among the lights passing through the color filter layer CF, lights passing through the first to third openings OPR, OPG, and OPB of the light shielding layer 200-SDL may be discharged to the outside of the display panel DP.

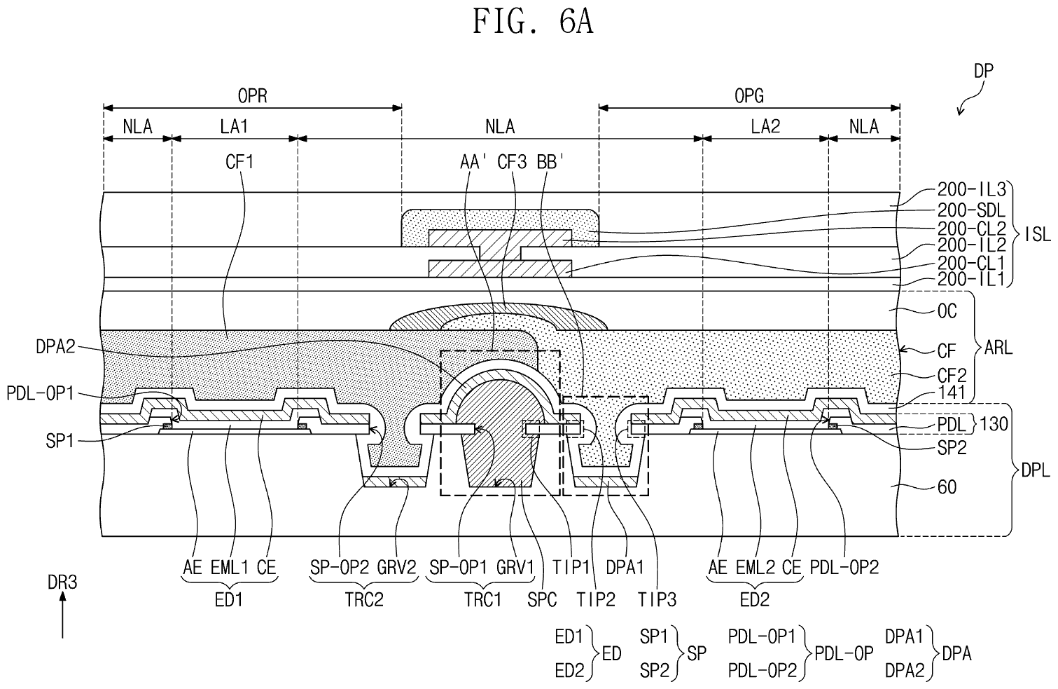

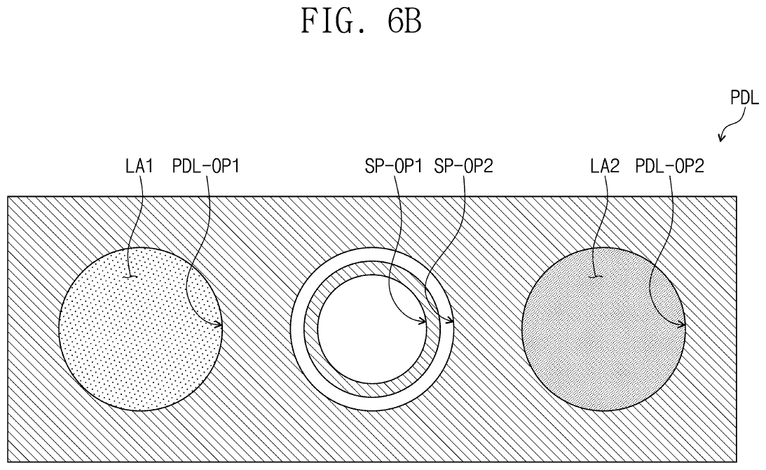

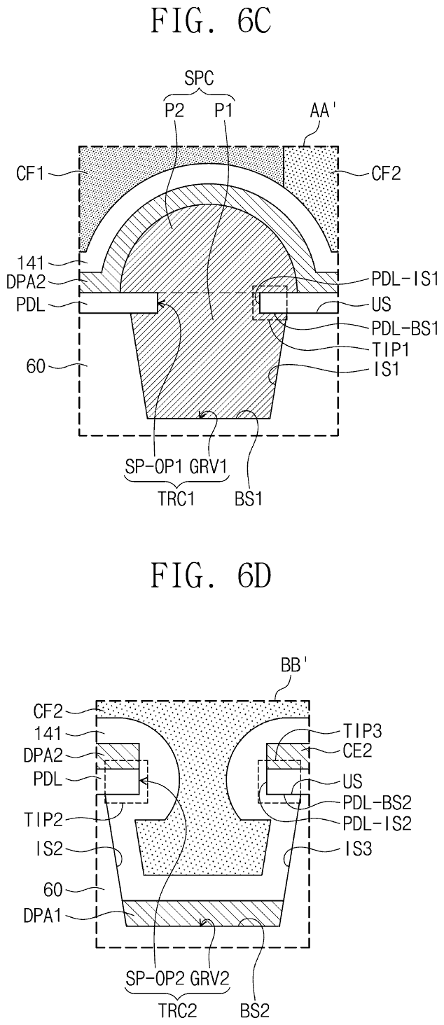

FIG. 6A is a cross-sectional view of the display panel DP according to an embodiment of the present disclosure. FIG. 6B is a plan view illustrating some components of the display panel DP (see FIG. 6A) according to an embodiment of the present disclosure. FIG. 6C is an enlarged cross-sectional view illustrating area AA′ of FIG. 6A. FIG. 6D is an enlarged cross-sectional view illustrating area BB′ of FIG. 6A. FIG. 6A is an enlarged view illustrating a portion of FIG. 5 and is an enlarged view illustrating the one first light emitting area LA1, the one second light emitting area LA2, and the non-light emitting area NLA surrounding the second light emitting area LA2 in a plan view (see FIG. 6A). FIG. 6B is an enlarged plan view illustrating a partial area of the pixel defining layer PDL among the components of the display panel DP (see FIG. 6A) and is an enlarged view illustrating the one first light emitting area LA1, the one second light emitting area LA2, and the non-light emitting area NLA surrounding the second light emitting area LA2 in a plan view, which is like FIG. 6A. Hereinafter, in description with reference to FIGS. 6A to 6D, the same/similar reference numerals are used for the same/similar components described in FIGS. 3 to 5, and a duplicated description thereof will be omitted.

Referring to FIGS. 6A to 6D, the display panel DP according to an embodiment may include a first trench TRC1 and a second trench TRC2. Each of the first trench TRC1 and the second trench TRC2 may be defined inside the sixth insulating layer 60 and the pixel defining layer PDL. The first and second trenches TRC1 and TRC2 may be spaced apart from the first and second light emitting openings PDL-OP1 and PDL-OP2. A spacer SPC may be disposed in the first trench TRC1. The second trench TRC2 may surround the first trench TRC1 in a plan view. Hereinafter, the first trench TRC1 and the second trench TRC2 will be described in detail.

A first groove GRV1 may be defined in the sixth insulating layer 60 by removing a portion of the sixth insulating layer 60 in the thickness direction (i.e., the third direction DR3). A second groove GRV2 may be defined in the sixth insulating layer 60 by removing a portion of the sixth insulating layer 60 in the thickness direction (i.e., the third direction DR3). The second groove GRV2 may surround the first groove GRV1 in a plan view. On a plane, the second groove GRV2 may have a ring shape that surrounds the first groove GRV1.

The sixth insulating layer 60 may include an upper surface US, a first inner surface IS1 and a first bottom surface BS1 that define the first groove GRV1, and a second inner surface IS2, a third inner surface IS3, and a second bottom surface BS2 that define the second groove GRV2. The first inner surface IS1 may connect the upper surface US and the first bottom surface BS1. The second and third inner surfaces IS2 and IS3 may connect the upper surface US and the second bottom surface BS2. The second and third inner surfaces IS2 and IS3 may face each other, and the second inner surface IS2 may be arranged closer to the first groove GRV1 than the third inner surface IS3.

First and second spacing openings SP-OP1 and SP-OP2 may be defined in the pixel defining layer PDL. The first and second spacing openings SP-OP1 and SP-OP2 may be arranged spaced apart from the light emitting openings PDL-OP.

As illustrated in FIGS. 6A and 6C, the first spacing opening SP-OP1 may overlap the first groove GRV1 in a plan view. The first spacing opening SP-OP1 and the first groove GRV1 may form an integral space. The first trench TRC1 may be provided by the first spacing opening SP-OP1 and the first groove GRV1 formed in the integral space.

A portion of the pixel defining layer PDL may protrude from the first inner surface IS1 of the sixth insulating layer 60 that defines the first groove GRV1 in a direction toward a center of the first groove GRV1. That is, the portion of the pixel defining layer PDL may overlap the first groove GRV1 in a plan view. The portion of the pixel defining layer PDL that protrudes from the first inner surface IS1 may define a first tip portion TIP1.

The sixth insulating layer 60 and the pixel defining layer PDL in which the first trench TRC1 is defined may have an undercut shape or overhang structure. On a cross sectional view, a width of the first spacing opening SP-OP1 in one direction parallel to a plane defined by the first and second directions DR1 and DR2 may be smaller than a maximum width of the first groove GRV1 in the one direction.

As illustrated in FIGS. 6A and 6D, the second spacing opening SP-OP2 may overlap the second groove GRV2 in a plan view. The second spacing opening SP-OP2 and the second groove GRV2 may form an integral space. The second trench TRC2 may be provided by the second spacing opening SP-OP2 and the second groove GRV2 formed in the integral space.

The portion of the pixel defining layer PDL may protrude from the second inner surface IS2 of the sixth insulating layer 60 that defines the second groove GRV2 in a direction away from the first groove GRV1. The portion of the pixel defining layer PDL may protrude from one inner edge of the sixth insulating layer 60 that defines the second groove GRV2. That is, the portion of the pixel defining layer PDL may overlap the second groove GRV2 in a plan view. The portion of the pixel defining layer PDL that protrudes from the second inner surface IS2 may define a second tip portion TIP2. The other portion of the pixel defining layer PDL may protrude from the third inner surface IS3 of the sixth insulating layer 60 that defines the second groove GRV2 in a direction toward the first groove GRV1. The other portion of the pixel defining layer PDL may protrude from the other inner edge of the sixth insulating layer 60 that defines the second groove GRV2. That is, the other portion of the pixel defining layer PDL may overlap the second groove GRV2 in a plan view. The other portion of the pixel defining layer PDL that protrudes from the third inner surface IS3 may define a third tip portion TIP3. The sixth insulating layer 60 and the pixel defining layer PDL in which the first and second trenches TRC1 and TRC2 are defined may have an undercut shape or overhang structure. On a cross sectional view, a width of the second spacing opening SP-OP2 in one direction parallel to a plane defined by the first and second directions DR1 and DR2 may be smaller than a maximum width of the second groove GRV2 in the one direction.

FIG. 6B illustratively illustrates that the first spacing opening SP-OP1 has a circular shape on a plane and the second spacing opening SP-OP2 has a ring shape (or a hook shape or a closed curve shape) on a plane (i.e., in a plan view), but the shapes of the first spacing opening SP-OP1 and the second spacing opening SP-OP2 are not limited thereto. For another example, the first spacing opening SP-OP1 may have an elliptical shape or a polygonal shape, and the second spacing opening SP-OP2 may have various shapes as long as the second spacing opening SP-OP2 is provided to surround the first spacing opening SP-OP1 in a plan view.

As illustrated in FIGS. 6A and 6C, at least a portion of the spacer SPC may be disposed in the first trench TRC1. That is, at least a portion of the spacer SPC may be disposed in the first spacing opening SP-OP1 and the first groove GRV1. The spacer SPC may include a first portion P1 disposed in the first trench TRC1 and a second portion P2 extending from the first portion P1 and protruding in a direction away from the first spacing opening SP-OP1 (i.e., the third direction DR3).

The first portion P1 of the spacer SPC may be in contact with the first inner surface IS1 and the first bottom surface BS1 of the sixth insulating layer 60 that defines the first groove GRV1. Further, the first portion P1 of the spacer SPC may be in contact with an inner surface PDL-IS1 of the pixel defining layer PDL that defines the first spacing opening SP-OP1 and a lower surface PDL-BS1 of the pixel defining layer PDL exposed from the sixth insulating layer 60. That is, the first portion P1 of the spacer SPC may be in contact with the first tip portion TIP1. As a portion of the spacer SPC is disposed inside the first trench TRC1, an area in which the spacer SPC is in contact with the sixth insulating layer 60 and the pixel defining layer PDL may be increased, and an adhesive force of the spacer SPC may be improved. Accordingly, the spacer SPC may be provided in a relatively decreased width.

The second portion P2 of the spacer SPC may have a shape protruding from the pixel defining layer PDL and thus may support a fine metal mask (“FMM”) in a process of forming the first and second light emitting layers EML1 and EML2.

The spacer SPC may be disposed in an island structure of the pixel defining layer PDL. In detail, the first spacing opening SP-OP1 and the second spacing opening SP-OP2 that completely surrounds the first spacing opening SP-OP1 in a plan view are defined in the pixel defining layer PDL, and thus the portion of the pixel defining layer PDL may be provided in the form of a spaced pattern. After the process of forming the first and second light emitting layers EML1 and EML2, even when foreign substances remain in the spacer SPC or the spacer SPC is damaged due to scratches of the FMM, the spacer SPC is disposed in the island structure of the pixel defining layer PDL spaced by the second spacing opening SP-OP2, and thus a phenomenon in which defects of the first and second light emitting elements ED1 and ED2 are caused by the remaining foreign substances or the damage to the spacer SPC may be effectively reduced or prevented.

The display panel DP according to an embodiment may further include a dummy pattern DPA. The dummy pattern DPA may include first and second dummy patterns DPA1 and DPA2. The first dummy pattern DPA1 may be disposed inside the second groove GRV2. The second dummy pattern DPA2 may be disposed on the pixel defining layer PDL and may cover the spacer SPC. The second dummy pattern DPA2 may overlap the first trench TRC1 in a plan view.

The first and second dummy patterns DPA1 and DPA2 may be spaced apart from the second electrode CE. The first and second dummy patterns DPA1 and DPA2 may include the same material as the second electrode CE and may be formed through the same process as the second electrode CE. That is, the first and second dummy patterns DPA1 and DPA2 may be simultaneously formed as portions thereof are separated by the second and third tip portions TIP2 and TIP3 in a process of forming the second electrode CE and thus are spaced apart from the second electrode CE. The dummy pattern DPA may be referred to as a dummy electrode. In another embodiment, the dummy pattern DPA may be removed or may not be formed according to an embodiment.

The inorganic encapsulation film 141 may be disposed on the second electrode CE and the spacer SPC. The inorganic encapsulation film 141 may cover the second electrode CE and the dummy pattern DPA. A portion of the inorganic encapsulation film 141 may be disposed inside the second trench TRC2. The inorganic encapsulation film 141 may be in contact with an inner surface PDL-IS2 of the pixel defining layer PDL that defines the second spacing opening SP-OP2 and a lower surface PDL-BS2 of the pixel defining layer PDL exposed from the upper surface US of the sixth insulating layer 60. Further, the inorganic encapsulation film 141 may be in contact with the second and third inner surfaces IS2 and IS3 of the sixth insulating layer 60 that defines the second groove GRV2 and may be in contact with the first dummy pattern DPA1 inside the second groove GRV2. The inorganic encapsulation film 141 may cover the second dummy pattern DPA2.

The inorganic encapsulation film 141 may be in contact with the second and third tip portions TIP2 and TIP3. Since the second and third tip portions TIP2 and TIP3 may have a protruding form from the second and third inner surfaces IS2 and IS3, and the inorganic encapsulation film 141 may surround this protrusion, permeation paths of moisture, oxygen, and dust particles from the outside to the light emitting element ED may be prolonged (i.e., thicker). Accordingly, permeation to the light emitting element ED may be delayed or prevented. Further, the permeation of the moisture to the light emitting element ED may be prevented such that it prevents defects of the light emitting element ED. For example, growing dark spot (“GDS”) defects that are caused by the permeation of the moisture, the oxygen, and the dust particles may be reduced. Therefore, the display device DD (see FIG. 1) having improved display quality may be provided.

Some of the first to third color filters CF1, CF2, and CF3 may be arranged inside the second trench TRC2. That is, some of the first to third color filters CF1, CF2, and CF3 may be arranged inside the second spacing opening SP-OP2 and the second groove GRV2. Some of the first to third color filters CF1, CF2, and CF3 may be arranged inside the second trench TRC2 and in contact with the inorganic encapsulation film 141. FIG. 6A illustratively illustrates that the first color filter CF1 is disposed in a partial area of the second trench TRC2, which is adjacent to the first light emitting element ED1, and the second color filter CF2 is disposed in a partial area of the second trench TRC2, which is adjacent to the second light emitting element ED2. However, the types of color filters CF1, CF2, and CF3 arranged inside the second trench TRC2 may be changed according to a position of the second trench TRC2.

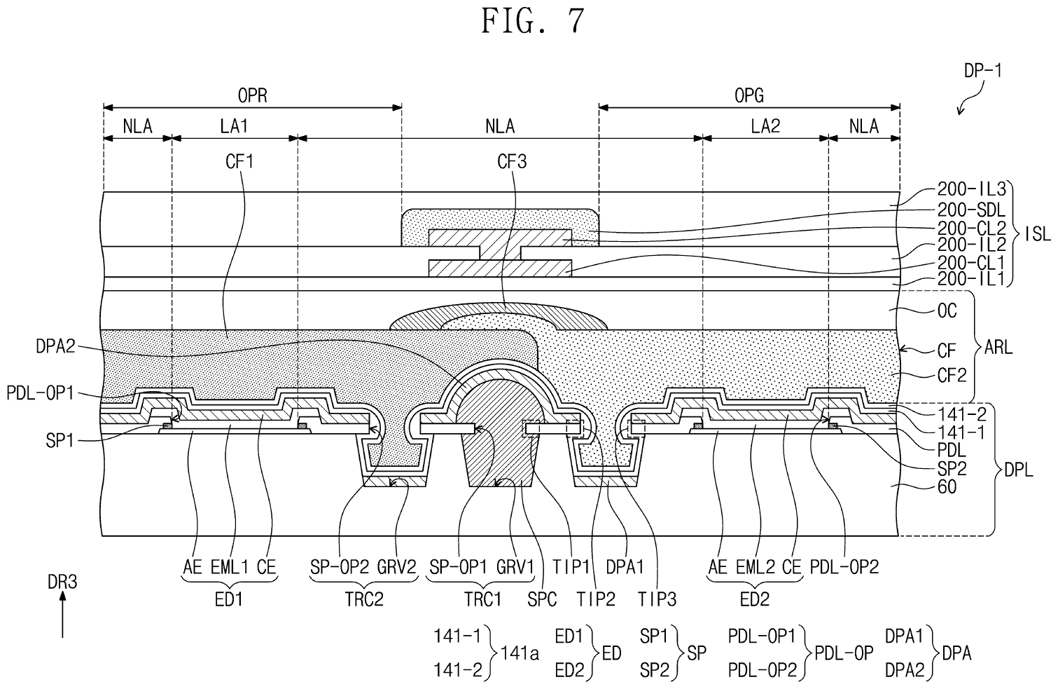

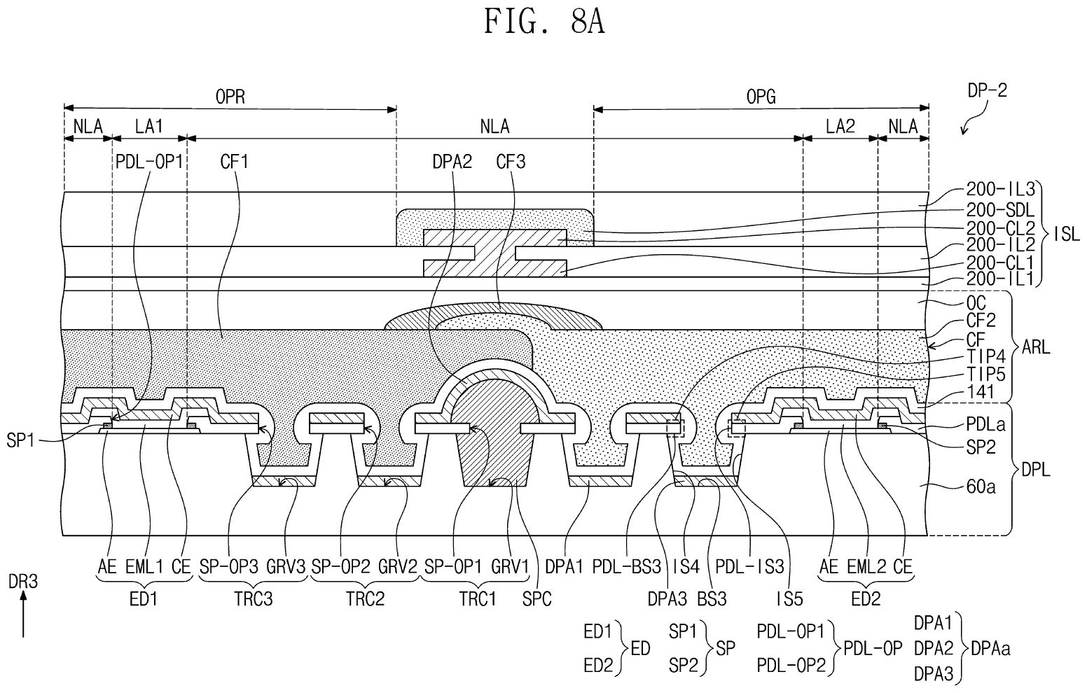

FIG. 7 is a cross-sectional view of a display panel DP-1 according to an embodiment of the present disclosure. FIG. 7 is an enlarged view illustrating a portion of FIG. 5 and is an enlarged view illustrating the one first light emitting area LA1, the one second light emitting area LA2, and the non-light emitting area NLA surrounding the second light emitting area LA2 in a plan view. Hereinafter, in description with reference to FIG. 7, the same/similar reference numerals are used for the same/similar components described in FIGS. 3 to 6D, and a duplicated description thereof reference will be omitted.

Referring to FIG. 7, the display panel DP-1 according to an embodiment of the present disclosure may include an inorganic encapsulation film 141a having a multi-layer structure in which layers are laminated in the third direction DR3. The inorganic encapsulation film 141a may include a first inorganic encapsulation film 141-1 and a second inorganic encapsulation film 141-2.

The second inorganic encapsulation film 141-2 may be directly disposed on the first inorganic encapsulation film 141-1. The second inorganic encapsulation film 141-2 may include a silicon nitride layer, a silicon oxy nitride layer, a silicon oxide layer, a titanium oxide layer, an aluminum oxide layer, or the like. When the first and second inorganic encapsulation films 141-1 and 141-2 are deposited, an atomic layer deposition (“ALD”) process and a chemical vapor deposition (“CVD”) process may be used. Both the first and second inorganic encapsulation films 141 and 142 may be formed by the ALD process or both the first and second inorganic encapsulation films 141 and 142 may be formed by the CVD process. Alternatively, the first and second inorganic encapsulation films 141 and 142 may be formed by the ALD process and the CVD process or may be formed by the CVD process and the ALD process. When the first and second inorganic encapsulation films 141 and 142 are formed by the ALD process, an encapsulation film that is uniform and thin may be provided as compared to a case in which the first and second inorganic encapsulation films 141 and 142 are formed by the CVD process.

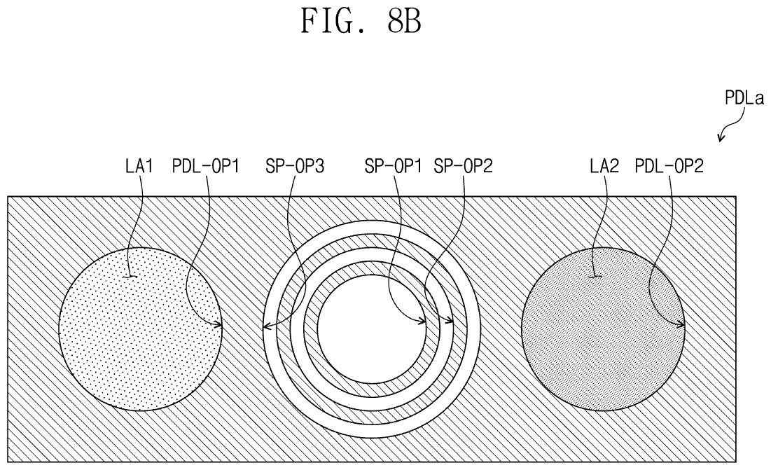

FIG. 8A is a cross-sectional view of a display panel DP-2 according to an embodiment of the present disclosure. FIG. 8B is an enlarged plan view illustrating a partial configuration of the display panel DP-2 (see FIG. 8A) according to an embodiment of the present disclosure. FIG. 8A is an enlarged view illustrating a portion of FIG. 5 and is an enlarged view illustrating the one first light emitting area LA1, the one second light emitting area LA2, and the non-light emitting area NLA surrounding the second light emitting area LA2 in a plan view. FIG. 8B is an enlarged plan view illustrating a partial area of the pixel defining layer PDL among the components of the display panel DP-2 (see FIG. 8A) and is an enlarged view illustrating the one first light emitting area LA1, the one second light emitting area LA2, and the non-light emitting area NLA surrounding the second light emitting area LA2 in a plan view, which is like FIG. 8A. Hereinafter, in description with reference to FIGS. 8A and 8B, the same/similar reference numerals are used for the same/similar components described in FIGS. 3 to 6D, and a duplicated description thereof will be omitted.

Referring to FIGS. 8A and 8B, the display panel DP-2 according to an embodiment of the present disclosure may further include a third trench TRC3. The third trench TRC3 may be defined inside a sixth insulating layer 60a and a pixel defining layer PDLa. The third trench TRC3 may be spaced apart from the first and second light emitting openings PDL-OP1 and PDL-OP2. The third trench TRC3 may surround the second trench TRC2 in a plan view. Hereinafter, the third trench TRC3 will be described in detail.

A third groove GRV3 may be additionally defined in the sixth insulating layer 60a by removing a portion of the sixth insulating layer 60a in the thickness direction (i.e., the third direction DR3). The third groove GRV3 may surround the second groove GRV2 in a plan view. On a plane, the third groove GRV3 may have a ring shape that surrounds the second groove GRV2.

The sixth insulating layer 60a may further include a fourth inner surface IS4, a fifth inner surface IS5, and a third bottom surface BS3 that define the third groove GRV3. The fourth and fifth inner surfaces IS4 and IS5 may connect an upper surface and the third bottom surface BS3 of the sixth insulating layer 60a. The fourth and fifth inner surfaces IS4 and IS5 may face each other, and the fourth inner surface IS4 may be arranged closer to the first and second grooves GRV1 and GRV2 than the fifth inner surface IS5.

A third spacing opening SP-OP3 may be additionally defined in the pixel defining layer PDLa. The third spacing opening SP-OP3 may be spaced apart from the light emitting openings PDL-OP1 and PDL-OP2.

The third spacing opening SP-OP3 may overlap the third groove GRV3 in a plan view. The third spacing opening SP-OP3 and the third groove GRV3 may form an integral space. The third trench TRC3 may be provided by the third spacing opening SP-OP3 and the third groove GRV3 formed in the integral space.

A portion of the pixel defining layer PDLa may protrude from the fourth inner surface IS4 of the sixth insulating layer 60a that defines the third groove GRV3 in a direction away from the second groove GRV2. That is, the portion of the pixel defining layer PDLa may overlap the third groove GRV3 in a plan view. The portion of the pixel defining layer PDLa that protrudes from the fourth inner surface IS4 may define a fourth tip portion TIP4. The other portion of the pixel defining layer PDLa may protrude from the fifth inner surface IS5 of the sixth insulating layer 60a that defines the third groove GRV3 in a direction toward the second groove GRV2. That is, the other portion of the pixel defining layer PDLa may overlap the third groove GRV3 in a plan view. The other portion of the pixel defining layer PDLa that protrudes from the fifth inner surface IS5 may define a fifth tip portion TIP5. The sixth insulating layer 60a and the pixel defining layer PDLa in which the third trench TRC3 is defined may have an undercut shape or overhang structure. On a cross sectional view, a width of the third spacing opening SP-OP3 in one direction parallel to a plane defined by the first and second directions DR1 and DR2 may be smaller than the maximum width of the third groove GRV3 in the one direction.

FIG. 8B illustratively illustrates that the first spacing opening SP-OP1 has a circular shape on a plane and the second and third spacing openings SP-OP2 and SP-OP3 have a ring shape on a plane (i.e., in a plan view), but the shapes of the first spacing opening SP-OP1 and the second and third spacing openings SP-OP2 and SP-OP3 are not limited thereto. For another example, the first spacing opening SP-OP1 may have an elliptical shape or a polygonal shape, and the second and third spacing openings SP-OP2 and SP-OP3 may have various shapes as long as the second and third spacing openings SP-OP2 and SP-OP3 are provided to surround the first spacing opening SP-OP1 in a plan view.

The display panel DP-2 according to an embodiment of the present disclosure may further include a dummy pattern DPAa, and the dummy pattern DPAa may include the first dummy pattern DPA1, the second dummy pattern DPA2, and a third dummy pattern DPA3. That is, in the display panel DP-2 according to an embodiment of the present disclosure, the dummy pattern DPAa may further include the third dummy pattern DPA3. The third dummy pattern DPA3 may be disposed inside the third groove GRV3. The third dummy pattern DPA3 may overlap the third trench TRC3 in a plan view.

The third dummy pattern DPA3 may be spaced apart from the second electrode CE. The third dummy pattern DPA3 may include the same material as the second electrode CE and may be formed in the same process as the second electrode CE. That is, the third dummy pattern DPA3 may be simultaneously formed as portions thereof are separated by the fourth and fifth tip portions TIP4 and TIP5 in the process of forming the second electrode CE and thus are spaced apart from the second electrode CE. The third dummy pattern DPA3 may be spaced apart from the first and second dummy patterns DPA1 and DPA2 and may be simultaneously formed.

The inorganic encapsulation film 141 may be disposed on the second electrode CE and the spacer SPC. The inorganic encapsulation film 141 may cover the second electrode CE and the dummy pattern DPAa. A portion of the inorganic encapsulation film 141 may be disposed inside the third trench TRC3. The inorganic encapsulation film 141 may be in contact with an inner surface PDL-IS3 of the pixel defining layer PDLa that defines the third spacing opening SP-OP3, and a lower surface PDL-BS3 of the pixel defining layer PDLa exposed from an upper surface of the sixth insulating layer 60a. Further, the inorganic encapsulation film 141 may be in contact with the fourth and fifth inner surfaces IS4 and IS5 of the sixth insulating layer 60a that defines the third groove GRV3 and may be in contact with the third dummy pattern DPA3 inside the third groove GRV3. The inorganic encapsulation film 141 may cover the third dummy pattern DPA3.

The inorganic encapsulation film 141 may be in contact with the fourth and fifth tip portions TIP4 and TIP5. the fourth and fifth tip portions TIP4 and TIP5 may have a protruding form from the fourth and fifth inner surfaces IS4 and IS5, the inorganic encapsulation film 141 may surround this protrusion, and thus the permeation paths of moisture, oxygen, and dust particles from the outside to the light emitting element ED may be prolonged (i.e., thicker). Accordingly, the permeation to the light emitting element ED may be delayed or prevented. Further, the permeation of the moisture to the light emitting element ED may be prevented such that it prevents defects of the light emitting element ED. For example, GDS defects that are caused by the permeation of the moisture, the oxygen, and the dust particles may be reduced. Therefore, the display device DD (see FIG. 1) having improved display quality may be provided.

Some of the first to third color filters CF1, CF2, and CF3 may be arranged inside the third trench TRC3. That is, some of the first to third color filters CF1, CF2, and CF3 may be arranged inside the third spacing opening SP-OP3 and the third groove GRV3. Some of the first to third color filters CF1, CF2, and CF3 may be arranged inside the third trench TRC3 and in contact with the inorganic encapsulation film 141. FIG. 8A illustratively illustrates that the first color filter CF1 is disposed in a partial area of the third trench TRC3, which is adjacent to the first light emitting element ED1, and the second color filter CF2 is disposed in a partial area of the third trench TRC3, which is adjacent to the second light emitting element ED2. However, the types of color filters CF1, CF2, and CF3 arranged inside the third trench TRC3 may be changed according to a position of the third trench TRC3.

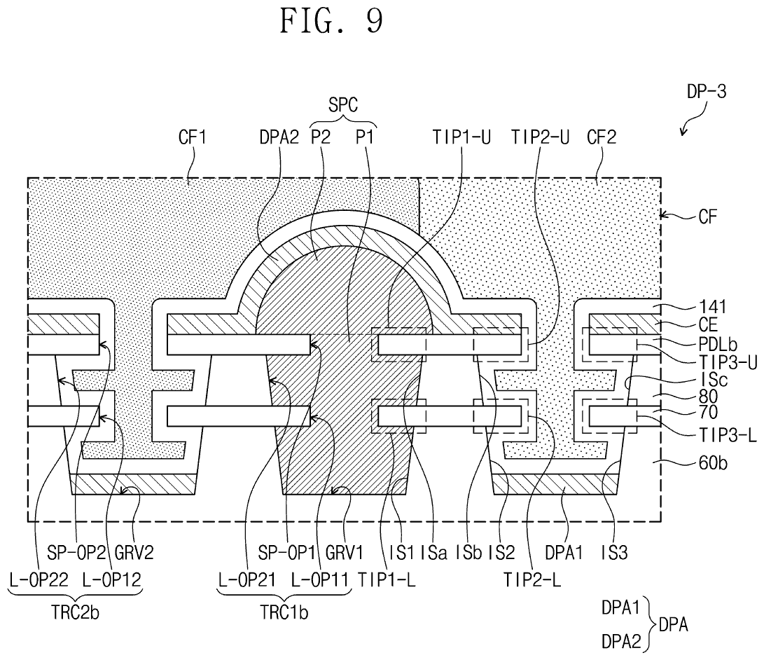

FIG. 9 is a cross-sectional view of a display panel DP-3 according to an embodiment of the present disclosure. Hereinafter, in description with reference to FIG. 9, the same/similar reference numerals are used for the same/similar components described in FIGS. 3 to 6D, and a duplicated description thereof reference will be omitted.

Referring to FIG. 9, the display panel DP-3 according to an embodiment of the present disclosure may further include a seventh insulating layer 70 and an eighth insulating layer 80.

The seventh insulating layer 70 may be disposed between a sixth insulating layer 60b and a pixel defining layer PDLb. A (1-1)^{th} lower opening L-OP11 and a (1-2)^{th} lower opening L-OP12 may be defined in the seventh insulating layer 70. The (1-1)^{th} lower opening L-OP11 and the (1-2)^{th} lower opening L-OP12 may be spaced apart from the light emitting openings PDL-OP (see FIG. 6A). The (1-1)^{th} lower opening L-OP11 may overlap the first groove GRV1 in a plan view. The (1-2)^{th} lower opening L-OP12 may overlap the second groove GRV2 in a plan view. The seventh insulating layer 70 may be referred to as a “first intermediate insulating layer”.

On a cross sectional view, a width of the (1-1)^{th} lower opening L-OP11 in one direction parallel to a plane defined by the first and second directions DR1 and DR2 may be smaller than the maximum width of the first groove GRV1 in the one direction. A portion of the seventh insulating layer 70 may protrude from a first inner surface IS1 of the sixth insulating layer 60b that defines the first groove GRV1 in a direction toward the center of the first groove GRV1. That is, the portion of the seventh insulating layer 70 may overlap the first groove GRV1 in a plan view. The portion of the seventh insulating layer 70 that protrudes from the first inner surface IS1 may define a first lower tip portion TIP1-L. The sixth insulating layer 60b, the seventh insulating layer 70, the eighth insulating layer 80, and the pixel defining layer PDLb in which a first trench TRC1b is defined may have an undercut shape or overhang structure.

On a cross sectional view, a width of the (1-2)^{th} lower opening L-OP12 in one direction parallel to a plane defined by the first and second directions DR1 and DR2 may be smaller than the maximum width of the second groove GRV2 in the one direction. The portion of the seventh insulating layer 70 may protrude from a second inner surface IS2 of the sixth insulating layer 60b that defines the second groove GRV2 in a direction away from the first groove GRV1. That is, the portion of the seventh insulating layer 70 may overlap the second groove GRV2 in a plan view. The portion of the seventh insulating layer 70 that protrudes from the second inner surface IS2 may define a second lower tip portion TIP2-L. The other portion of the seventh insulating layer 70 may protrude from a third inner surface IS3 of the sixth insulating layer 60b that defines the third groove GRV3 in a direction toward the first groove GRV1. That is, the other portion of the seventh insulating layer 70 may overlap the second groove GRV2 in a plan view. The other portion of the seventh insulating layer 70 that protrudes from the third inner surface IS3 may define a third lower tip portion TIP3-L.

The seventh insulating layer 70 may include an inorganic insulating material. For example, the seventh insulating layer 70 may include a silicon nitride (SiNₓ). In an embodiment, the seventh insulating layer 70 may include the same material as the pixel defining layer PDLb. However, an embodiment is not limited thereto.

The eighth insulating layer 80 may be disposed between the seventh insulating layer 70 and the pixel defining layer PDLb. A (2-1)^{th} lower opening L-OP21 and a (2-2)^{th} lower opening L-OP22 may be defined in the eighth insulating layer 80. The (2-1)^{th} lower opening L-OP21 and the (2-2)^{th} lower opening L-OP22 may be spaced apart from the light emitting openings PDL-OP (see FIG. 6A). The (2-1)^{th} lower opening L-OP21 may overlap the first groove GRV1 in a plan view. The (2-2)^{th} lower opening L-OP22 may overlap the second groove GRV2 in a plan view. The eighth insulating layer 80 may be referred to as a “second intermediate insulating layer”.

On a cross sectional view, a width of the (2-1)^{th} lower opening L-OP21 in one direction parallel to a plane defined by the first and second directions DR1 and DR2 may be greater than a width of the (1-1)^{th} lower opening L-OP11 in the one direction. The portion of the seventh insulating layer 70 that defines the first lower tip portion TIP1-L may protrude from an inner surface ISa of the eighth insulating layer 80 that defines the (2-1)^{th} lower opening L-OP21. On a cross sectional view, a width of the (2-2)^{th} lower opening L-OP22 in one direction parallel to a plane defined by the first and second directions DR1 and DR2 may be greater than a width of the (1-2)^{th} lower opening L-OP12 in the one direction. That is, the portion of the seventh insulating layer 70 may protrude from inner surfaces ISb and ISc of the eighth insulating layer 80 that defines the (2-2)^{th} lower opening L-OP22.

The eighth insulating layer 80 may be an organic layer. In an embodiment, the eighth insulating layer 80 may include the same material as the sixth insulating layer 60b. However, an embodiment is not limited thereto.

The pixel defining layer PDLb may be disposed on the eighth insulating layer 80. The first spacing opening SP-OP1 and the second spacing opening SP-OP2 may be defined in the pixel defining layer PDLb. The first spacing opening SP-OP1 may overlap the first groove GRV1, the (1-1)^{th} lower opening L-OP11, and the (2-1)^{th} lower opening L-OP21 in a plan view. The second spacing opening SP-OP2 may overlap the second groove GRV2, the (1-2)^{th} lower opening L-OP12, and the (2-2)^{th} lower opening L-OP22 in a plan view.

On a cross sectional view, a width of the first spacing opening SP-OP1 in one direction parallel to a plane defined by the first and second directions DR1 and DR2 may be smaller than the than a maximum width of the (2-1)^{th} lower opening L-OP21 in the one direction. In an embodiment, a portion of the pixel defining layer PDLb may protrude from the inner surface ISa of the eighth insulating layer 80 that defines the (2-1)^{th} lower opening L-OP21 in a direction toward the center of the first groove GRV1. That is, the portion of the pixel defining layer PDLb may overlap the (2-1)^{th} lower opening L-OP21 in a plan view. The portion of the pixel defining layer PDLb that protrudes from the inner surface ISa of the eighth insulating layer 80 that defines the (2-1)^{th} lower opening L-OP21 may define a first upper tip portion TIP1-U. The inner surface ISa of the eighth insulating layer 80 that defines the (2-1)^{th} lower opening L-OP21 may be recessed as compared to the seventh insulating layer 70 and the pixel defining layer PDLb.

On a cross sectional view, a width of the second spacing opening SP-OP2 in one direction parallel to a plane defined by the first and second directions DR1 and DR2 may be smaller than the than a maximum width of the (2-2)^{th} lower opening L-OP22 in the one direction. In an embodiment, the portion of the pixel defining layer PDLb may protrude from the inner surfaces ISb and ISc of the eighth insulating layer 80 that defines the (2-2)^{th} lower opening L-OP22 in a direction away from or toward the first groove GRV1. That is, the portion of the pixel defining layer PDLb may overlap the (2-2)^{th} lower opening L-OP22 in a plan view. The portion of the pixel defining layer PDLb, which protrudes from the inner surfaces ISb and ISc of the eighth insulating layer 80 that defines the (2-2)^{th} lower opening L-OP22, may define a second upper tip portion TIP2-U and a third upper tip portion TIP3-U. The second upper tip portion TIP2-U may protrude in a direction away from the first groove GRV1, and the third upper tip portion TIP3-U may protrude in a direction toward the first groove GRV1. The inner surfaces ISb and ISc of the eighth insulating layer 80 that defines the (2-2)^{th} lower opening L-OP22 may be recessed as compared to the seventh insulating layer 70 and the pixel defining layer PDLb.

The first groove GRV1, the (1-1)^{th} lower opening L-OP11, the (2-1)^{th} lower opening L-OP21, and the first spacing opening SP-OP1 may form an integral space. The first trench TRC1b may be provided by the first groove GRV1, the (1-1)^{th} lower opening L-OP11, the (2-1)^{th} lower opening L-OP21, and the first spacing opening SP-OP1 that are formed in the integral space. The sixth insulating layer 60b, the seventh insulating layer 70, the eighth insulating layer 80, and the pixel defining layer PDLb in which the first trench TRC1b is defined may have an undercut shape or overhang structure.

The second groove GRV2, the (2-2)^{th} lower opening L-OP22, the (1-2)^{th} lower opening L-OP12, and the second spacing opening SP-OP2 may form an integral space. A second trench TRC2b may be provided by the second groove GRV2, the (2-2)^{th} lower opening L-OP22, the (1-2)^{th} lower opening L-OP12, and the second spacing opening SP-OP2 that are formed in the integral space. The sixth insulating layer 60b, the seventh insulating layer 70, the eighth insulating layer 80, and the pixel defining layer PDLb in which the second trench TRC2b is defined may have an undercut shape or overhang structure. While FIG. 9 illustratively illustrates a structure in which two tip portions overlap each other in the thickness direction (i.e., third direction DR3), but the number of tip portions formed in the thickness direction is not limited.

At least a portion of the spacer SPC may be disposed inside the first trench TRC1b. That is, the at least a portion of the spacer SPC may be disposed inside the first groove GRV1, the (1-1)^{th} lower opening L-OP11, the (2-1)^{th} lower opening L-OP21, and the first spacing opening SP-OP1. The spacer SPC may include a first portion P1 disposed in the first trench TRC1b and a second portion P2 extending from the first portion P1 and protruding in a direction away from the first spacing opening SP-OP1.

The inorganic encapsulation film 141 may be disposed on the second electrode CE and the spacer SPC. The inorganic encapsulation film 141 may cover the second electrode CE and the dummy pattern DPA. A portion of the inorganic encapsulation film 141 may be disposed inside the second trench TRC2b. The inorganic encapsulation film 141 may be in contact with the second lower tip portion TIP2-L, the third lower tip portion TIP3-L, the second upper tip portion TIP2-U, and the third upper tip portion TIP3-U. Further, the inorganic encapsulation film 141 may be in contact with the inner surfaces of the seventh insulating layer 70 that defines the (1-2)^{th} lower opening L-OP12 and the inner surfaces ISb and ISc of the eighth insulating layer 80 that defines the (2-2)^{th} lower opening L-OP22. The inorganic encapsulation film 141 may be in contact with the first dummy pattern DPA1 inside the second groove GRV2. The inorganic encapsulation film 141 may cover the second dummy pattern DPA2.

The inorganic encapsulation film 141 surrounds the plurality of tip portions (e.g., the second lower tip portion TIP2-L, the third lower tip portion TIP3-L, the second upper tip portion TIP2-U, and the third upper tip portion TIP3-U), and thus the permeation paths of moisture, oxygen, and dust particles from the outside to the light emitting element ED may be prolonged (i.e., thicker). Accordingly, the permeation to the light emitting element ED may be delayed or prevented. Further, the permeation of the moisture to the light emitting element ED may be prevented such that it prevents defects of the light emitting element ED. For example, GDS defects that are caused by the permeation of the moisture, the oxygen, and the dust particles may be reduced. Therefore, the display device DD (see FIG. 1) having improved display quality may be provided.

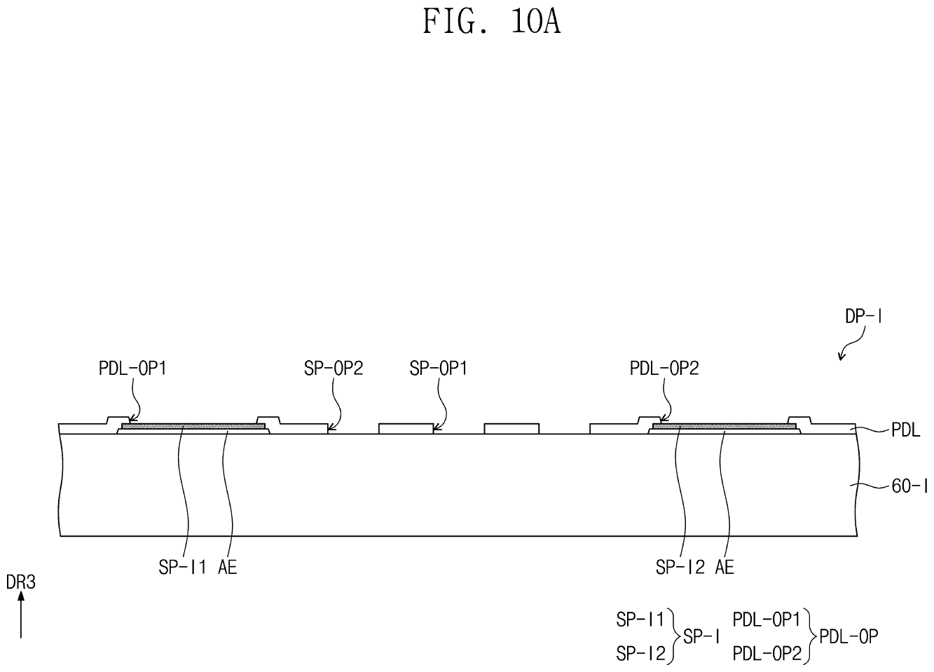

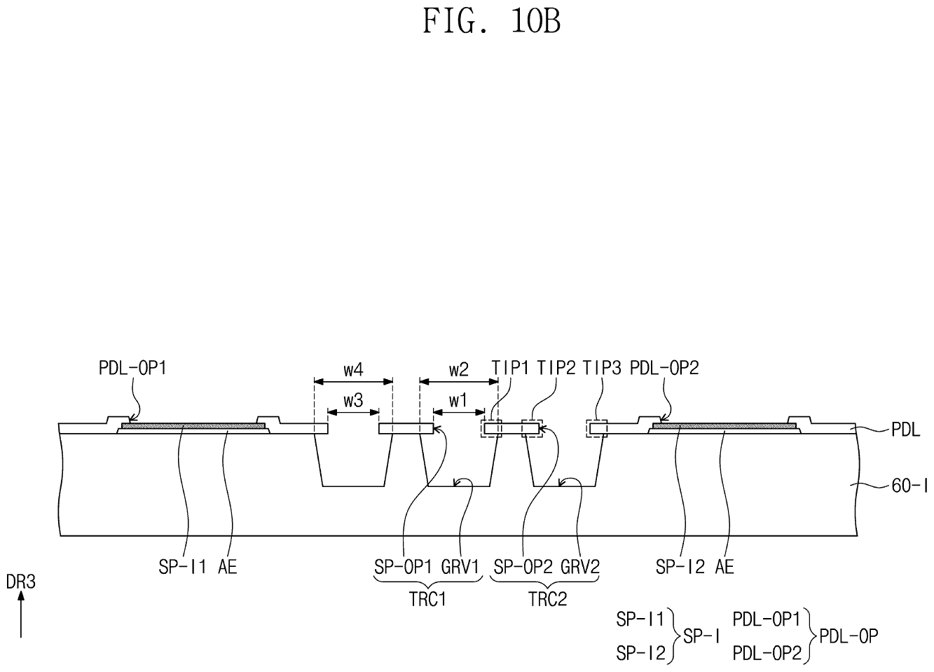

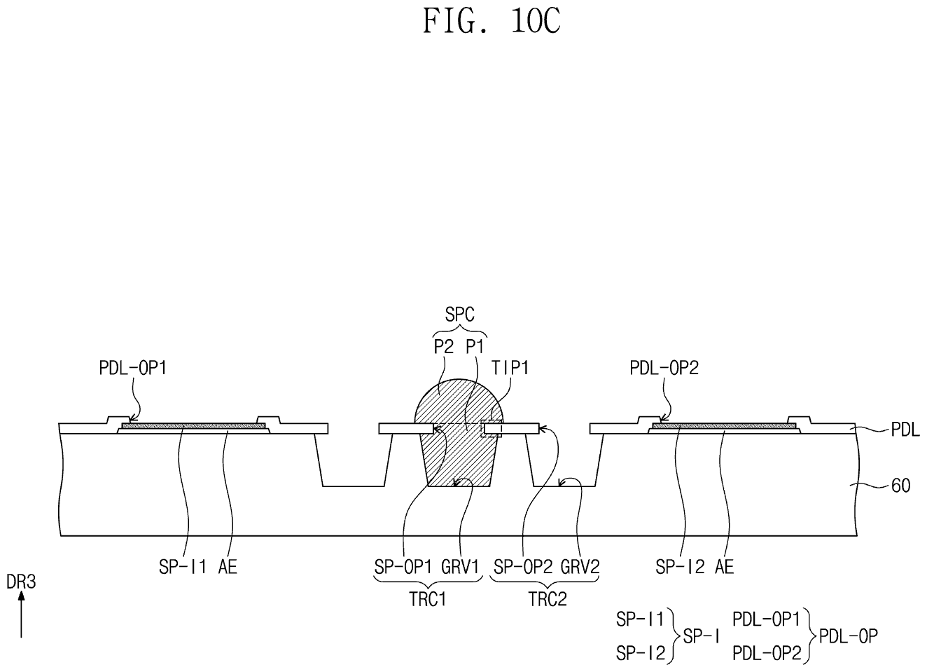

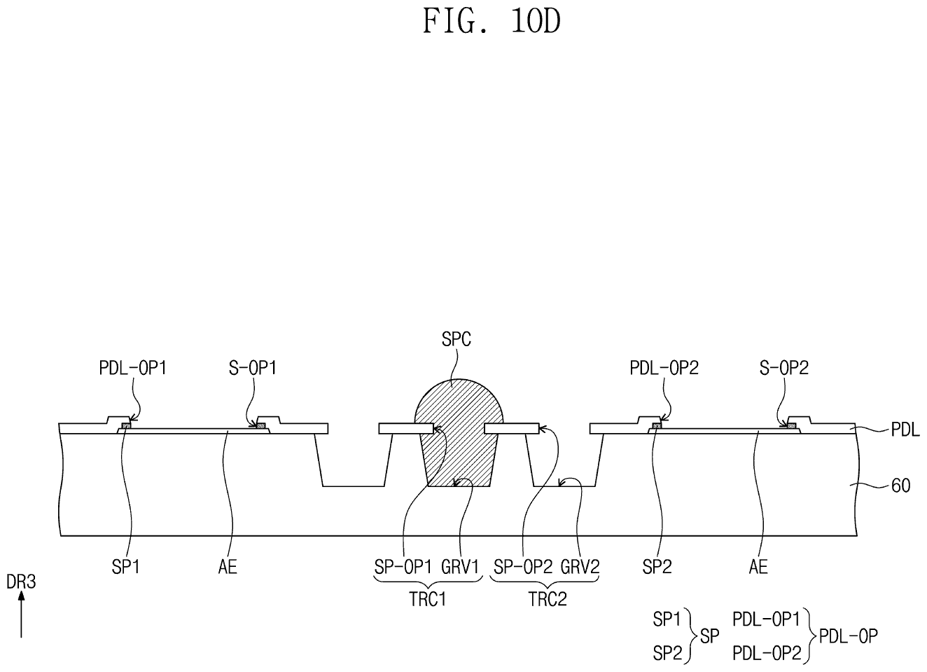

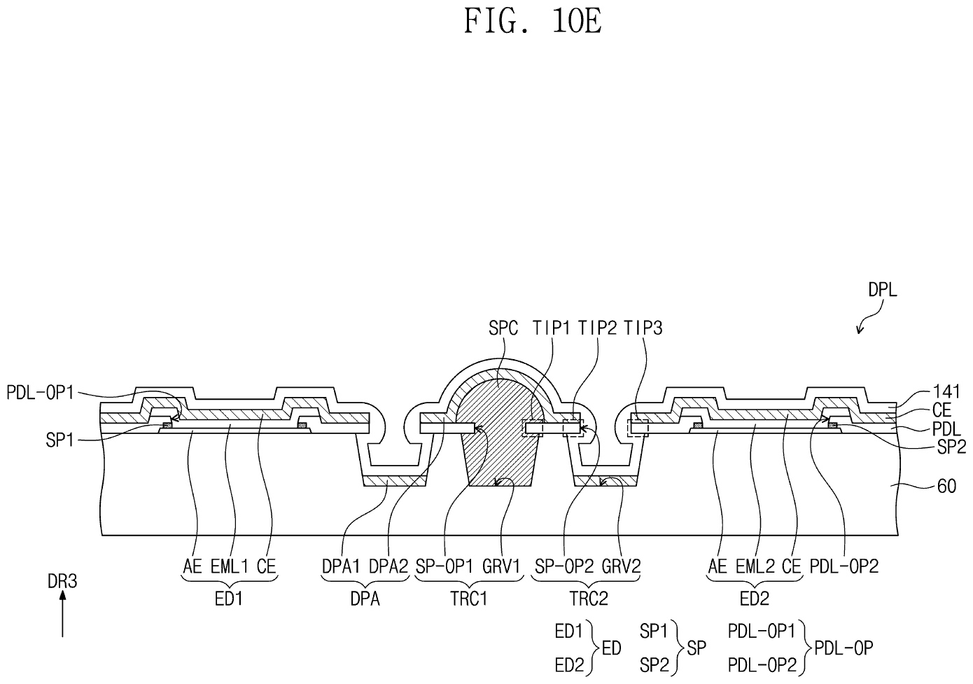

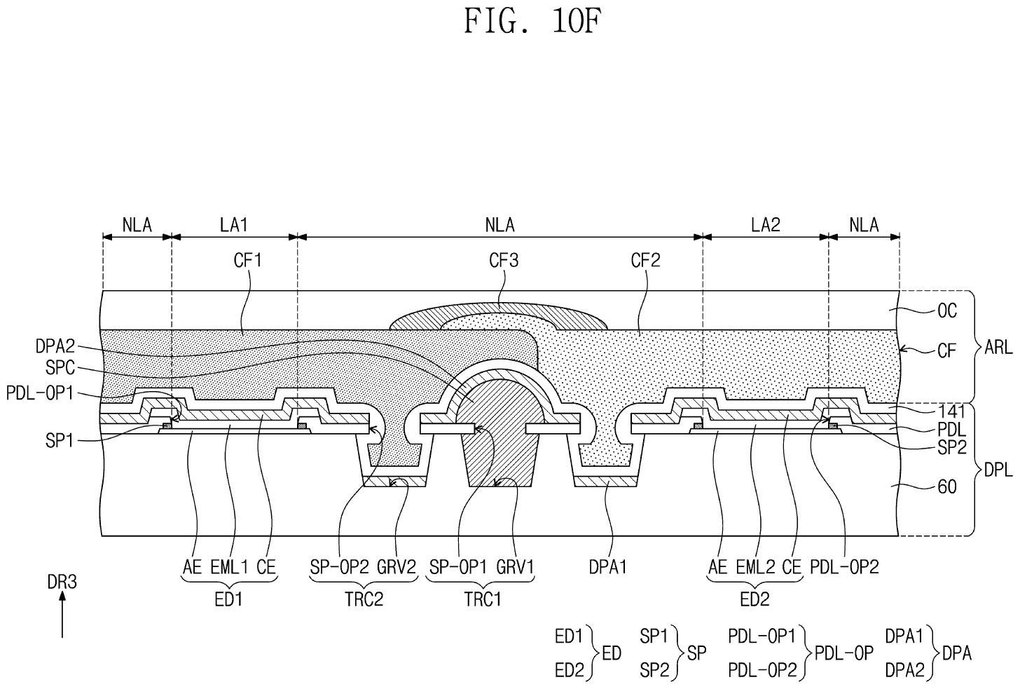

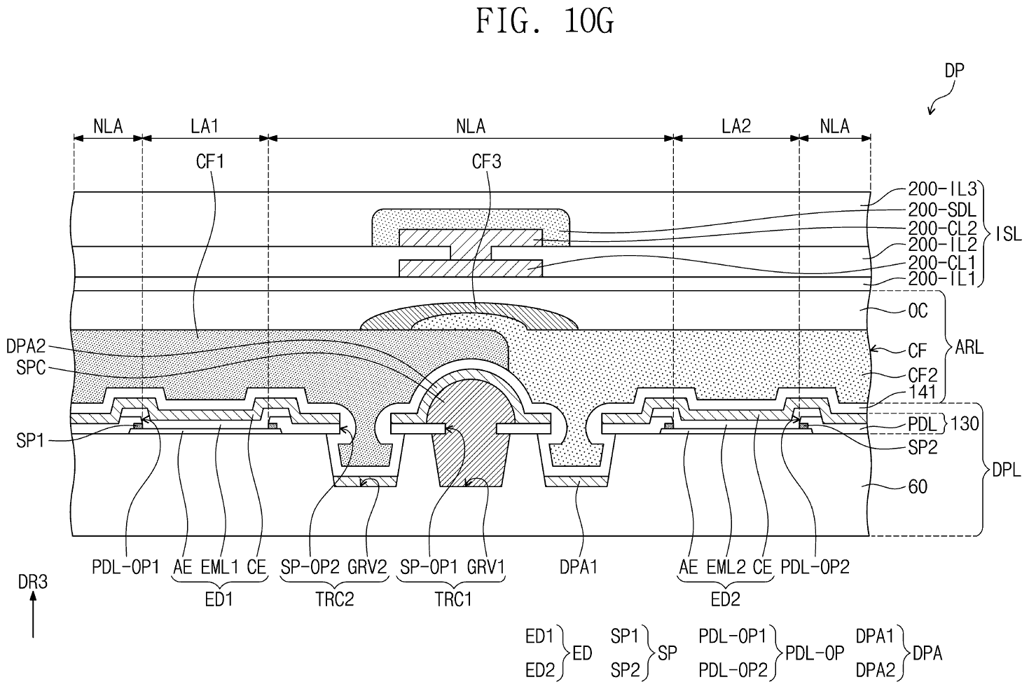

FIGS. 10A to 10G are cross-sectional views illustrating some of operations of a method of manufacturing the display panel DP according to an embodiment of the present disclosure. The same/similar reference numerals are used for the same/similar components described in FIGS. 1 to 9, and a duplicated description thereof will be omitted.

Referring to FIGS. 10A to 10G, the method of manufacturing the display panel DP according to an embodiment may include an operation of providing a preliminary display panel DP-I, an operation of etching an initial sixth insulating layer 60-I, an operation of forming the spacer SPC, an operation of etching an initial sacrificial pattern SP-I, an operation of performing heat treatment, an operation of forming the light emitting layer EML and the inorganic encapsulation film 141, an operation of forming the reflection preventing layer ARL, and an operation of forming the input sensor layer ISL.

As illustrated in FIG. 10A, the method of manufacturing the display panel DP (see FIG. 10G) according to an embodiment may include the operation of providing the preliminary display panel DP-I. The preliminary display panel DP-I provided in an embodiment includes the initial sixth insulating layer 60-1, the first electrode AE, the initial sacrificial pattern SP-I, and the pixel defining layer PDL. Although not illustrated in FIG. 10A, the preliminary display panel DP-I may further include the base layer 110 and the circuit layer 120 disposed on the base layer 110 described above in FIG. 4, and the circuit layer 120 may include the buffer layer 10br, the first to fifth insulating layers 10, 20, 30, 40, and 50, the signal transmitting area SCL, and the plurality of connection electrodes CNE1 and CNE2 described above in FIG. 4 and the initial sixth insulating layer 60-I illustrated in FIG. 10A.

The circuit layer 120 (see FIG. 4) may be formed by a general method of manufacturing a circuit element of forming an insulating layer, a semiconductor layer, and a conductive layer through a coating method or a deposition method, selectively patterning the insulating layer, the semiconductor layer, and the conductive layer by a photolithography and etching process, and forming a semiconductor pattern, a conductive pattern, a signal line or the like.

The light emitting opening PDL-OP, the first spacing opening SP-OP1, and the second spacing opening SP-OP2 may be defined in the pixel defining layer PDL.

The light emitting opening PDL-OP may expose a portion of the initial sacrificial pattern SP-I. The upper surface of the first electrode AE may be covered by the initial sacrificial pattern SP-I, and the first electrode AE may not be exposed by the light emitting opening PDL-OP.

The light emitting opening PDL-OP may be provided as a plurality of light emitting openings PDL-OP. FIG. 10A illustratively illustrates that the plurality of light emitting openings PDL-OP include the first light emitting opening PDL-OP1 and the second light emitting opening PDL-OP2.

The initial sacrificial pattern SP-I may be provided as a plurality of initial sacrificial patterns SP-I. FIG. 10A illustratively illustrates that the plurality of initial sacrificial patterns SP-I include a first initial sacrificial pattern SP-I1 of which a portion is exposed by the first light emitting opening PDL-OP1 and a second initial sacrificial pattern SP-I2 of which a portion is exposed by the second light emitting opening PDL-OP2.

The first spacing opening SP-OP1 and the second spacing opening SP-OP2 may be spaced apart from the light emitting openings PDL-OP. The second spacing opening SP-OP2 may surround the first spacing opening SP-OP1 in a plan view. The first spacing opening SP-OP1 may have a circular shape, an elliptical shape, or a polygonal shape on a plane (i.e., in a plan view), but the present disclosure is not limited thereto. Likewise, the second spacing opening SP-OP2 may have various shapes as long as the second spacing opening SP-OP2 is provided to surround the first spacing opening SP-OP1 in a plan view.

As illustrated in FIGS. 10A and 10B, the method of manufacturing the display panel DP (see FIG. 10G) according to an embodiment may include the operation of etching the initial sixth insulating layer 60-I to form the sixth insulating layer 60. In an embodiment, in the operation of etching the initial sixth insulating layer 60-I, the first groove GRV1 and the second groove GRV2 may be formed on the initial sixth insulating layer 60-I using the pixel defining layer PDL and the initial sacrificial pattern SP-I as a mask. That is, the sixth insulating layer 60-I in which the first groove GRV1 and the second groove GRV2 are defined may be formed through the operation of etching the initial sixth insulating layer 60-1. The first groove GRV1 may be formed to overlap the first spacing opening SP-OP1 of the pixel defining layer PDL in a plan view, and the second groove GRV2 may be formed to overlap the second spacing opening SP-OP2 of the pixel defining layer PDL in a plan view. In an embodiment, the process of etching the initial sixth insulating layer 60-I may be performed in a dry etching method.

According to an embodiment, the first and second grooves GRV1 and GRV2 may be formed using the pixel defining layer PDL and the initial sacrificial pattern SP-I as a mask without forming a separate mask. In more detail, a portion of the initial sixth insulating layer 60-I exposed from the pixel defining layer PDL by the first spacing opening SP-OP1 may be removed by an etching gas, and thus the first groove GRV1 corresponding to the first spacing opening SP-OP1 may be formed in the initial sixth insulating layer 60-I. The first spacing opening SP-OP1 and the first groove GRV1 may provide the first trench TRC1. A portion of the initial sixth insulating layer 60-I exposed from the pixel defining layer PDL by the second spacing opening SP-OP2 may be removed by an etching gas, and thus the second groove GRV2 corresponding to the second spacing opening SP-OP2 may be formed in the initial sixth insulating layer 60-I. The second spacing opening SP-OP2 and the second groove GRV2 may provide the second trench TRC2.

On a cross sectional view, the first groove GRV1 may be formed such that a maximum width w1 thereof is greater than a width w2 of the first spacing opening SP-OP1. Accordingly, the portion of the pixel defining layer PDL may protrude in a direction toward the center of the first groove GRV1. That is, the portion of the pixel defining layer PDL may overlap the first groove GRV1 in a plan view. In this case, the portion of the protruding pixel defining layer PDL may define the first tip portion TIP1.

On a cross sectional view, the second groove GRV2 may be formed such that a maximum width w3 thereof is greater than a width w4 of the second spacing opening SP-OP2. Accordingly, the portion of the pixel defining layer PDL may protrude in a direction away from the first groove GRV1. That is, the portion of the pixel defining layer PDL may overlap the second groove GRV2 in a plan view. In this case, the portion of the protruding pixel defining layer PDL may define the second tip portion TIP2. The other portion of the pixel defining layer PDL may protrude in a direction toward the center of the first groove GRV1. That is, the portion of the pixel defining layer PDL may overlap the second groove GRV2 in a plan view. In this case, the other portion of the protruding pixel defining layer PDL may define the third tip portion TIP3.

As illustrated in FIG. 10C, the method of manufacturing the display panel DP (see FIG. 10G) according to an embodiment may include the operation of forming the spacer SPC.

At least a portion of the spacer SPC may be arranged and formed inside the first spacing opening SP-OP1 and the first groove GRV1. The spacer SPC may include the first portion P1 disposed in the first trench TRC1 and the second portion P2 extending from the first portion P1 and protruding in a direction away from the first spacing opening SP-OP1.

The first portion P1 of the spacer SPC may be in contact with the first tip portion TIP1. As a portion of the spacer SPC is disposed inside the first trench TRC1, an area in which the spacer SPC is in contact with the sixth insulating layer 60 and the pixel defining layer PDL may be increased, and an adhesive force of the spacer SPC may be improved. Accordingly, the spacer SPC may be provided in a decreased width.

As illustrated in FIGS. 10C and 10D, the method of manufacturing the display panel DP (see FIG. 10G) according to an embodiment may include the operation of etching the initial sacrificial pattern SP-I to form the sacrificial pattern SP. In an embodiment, in the operation of etching the initial sacrificial pattern SP-I, the sacrificial opening S-OP may be formed in the initial sacrificial pattern SP-I using the pixel defining layer PDL as a mask. That is, the sacrificial pattern SP in which the sacrificial opening S-OP is defined may be formed through the operation of etching the initial sacrificial pattern SP-I. At least a portion of the first electrode AE may be exposed from the sacrificial pattern SP and the pixel defining layer PDL by the sacrificial opening S-OP and the light emitting opening PDL-OP.

In an embodiment, a process of etching the sacrificial pattern SP may be performed in a wet etch method.

The sacrificial pattern SP may be provided as a plurality of sacrificial patterns SP, and FIG. 10D illustratively illustrates that the first sacrificial pattern SP1 formed from the first initial sacrificial pattern SP-I1 (see FIG. 10C) and the second sacrificial pattern SP2 formed from the second initial sacrificial pattern SP-I2 (see FIG. 10C) are provided.

In more detail, a portion of the first initial sacrificial pattern SP-I1 exposed from the pixel defining layer PDL by the first light emitting opening PDL-OP1 may be removed, and thus the first sacrificial opening S-OP1 corresponding to the first light emitting opening PDL-OP1 may be formed in the first initial sacrificial pattern SP-I1. Therefore, the first sacrificial pattern SP1 in which the first sacrificial opening S-OP1 is defined may be formed from the first initial sacrificial pattern SP-I1.

A portion of the second initial sacrificial pattern SP-I2 exposed from the pixel defining layer PDL by the second light emitting opening PDL-OP2 may be removed, and thus the second sacrificial opening S-OP2 corresponding to the second light emitting opening PDL-OP2 may be formed in the second initial sacrificial pattern SP-I2. Therefore, the second sacrificial pattern SP2 in which the second sacrificial opening S-OP2 is defined may be formed from the second initial sacrificial pattern SP-I2.

The process of etching the sacrificial pattern SP may be performed in an environment in which etch selectivity between the sacrificial pattern SP and the first electrode AE is high, and therefore, the first electrode AE may be prevented from being etched together. That is, the sacrificial pattern SP having an etch rate that is greater than an etch rate of the first electrode AE is disposed between the pixel defining film PDL and the first electrode AE, and thus the first electrode AE may be prevented from being etched and damaged together during the etching process.

The method of manufacturing the display panel DP may further include the operation of performing the heat treatment after the process of etching the sacrificial pattern SP. The operation of performing the heat treatment may be performed after the process of etching the sacrificial pattern SP, and thus a gas generated from an organic layer, for example, the sixth insulating layer 60, disposed under the first electrode AE may be easily discharged. Accordingly, in the process of manufacturing the display panel DP (see FIG. 10F), the gas of the organic layer disposed under the light emitting element ED (see FIG. 10E) may be sufficiently discharged, and after the manufacturing, the gas discharged from the organic layer may be decreased, and thus a speed at which the light emitting element ED (see FIG. 10E) is degraded may be decreased. In this case, the gas of the organic layer may be more easily discharged through the first and second spacing openings SP-OP1 and SP-OP2 formed in the pixel defining layer PDL.

As illustrated in FIG. 10E, the method of manufacturing the display panel DP (see FIG. 10G) according to an embodiment may include an operation of forming the light emitting layer EML and the second electrode CE and the operation of forming the inorganic encapsulation film 141. Therefore, the display layer DPL may be completed.

First, in the operation of forming the light emitting layer EML and the second electrode CE, the light emitting layer EML and the second electrode CE may be sequentially arranged on the first electrode AE so that the light emitting element ED is formed.

Each of the operation of forming the light emitting layer EML and the operation of forming the second electrode CE may be performed through a deposition process. In an embodiment, the operation of forming the light emitting layer EML may be performed by a thermal evaporation process, and the operation of forming the second electrode CE may be performed by the CVD process. However, the present disclosure is not limited thereto.

The light emitting element ED may be provided as a plurality of light emitting elements ED. FIG. 10E illustratively illustrates that the first light emitting element ED1 including the first electrode AE, the first light emitting layer EML1, and the second electrode CE and the second light emitting element ED2 including the first electrode AE, the second light emitting layer EML2, and the second electrode CE are provided.

In the operation of forming the second electrode CE, the dummy pattern DPA spaced apart from the second electrode CE may be formed together. The dummy pattern DPA may include the first dummy pattern DPA1 and the second dummy pattern DPA2. The first and second dummy patterns DPA1 and DPA2 may be partially separated by the second and third tip portions TIP2 and TIP3 formed on the pixel defining layer PDL in the process of forming the second electrode CE and thus may be simultaneously formed. The first dummy pattern DPA1 may be formed inside the second groove GRV2. The second dummy pattern DPA2 may be disposed on the pixel defining layer PDL and may cover the spacer SPC.

Thereafter, in the operation of forming the inorganic encapsulation film 141, the inorganic encapsulation film 141 may be formed through the deposition process. In an embodiment, the inorganic encapsulation film 141 may include an inorganic material and, for example, may include a silicon nitride (SiNₓ). For example, the inorganic encapsulation film 141 may be formed through the CVD process and/or the ALD process.

As illustrated in FIG. 10F, the method of manufacturing the display panel DP (see FIG. 10G) according to an embodiment may include the operation of forming the reflection preventing layer ARL.

The reflection preventing layer ARL may include the color filter layer CF and the overcoat layer OC. The color filter layer CF may be directly disposed and formed on the display layer DPL. That is, the color filter layer CF may be directly disposed on the inorganic encapsulation film 141. Accordingly, the color filter layer CF may cover the second electrode CE of the light emitting element ED. Accordingly, reflection of an external light caused by the electrodes in the display layer DPL may be effectively reduced or prevented.

In an embodiment of the present disclosure, at least some of the first to third color filters CF1, CF2, and CF3 may overlap each other in an area which does not overlap any of the first to third light emitting areas LA1, LA2, and LA3 (see FIG. 5). That is, the at least some of the first to third color filters CF1, CF2, and CF3 may be arranged in a laminated form in the third direction DR3 in areas that overlap the non-light emitting area NLA. The first to third color filters CF1, CF2, and CF3 that overlap each other in the thickness (i.e., third direction DR3) direction may shield the light passing through the non-light emitting area NLA to prevent color mixing between the first to third light emitting areas LA1, LA2, and LA3 (see FIG. 5). However, an embodiment is not limited thereto, and in another embodiment the first to third color filters CF1, CF2, and CF3 may not be arranged to overlap each other in the thickness direction in a plan view.

In an embodiment, the overcoat layer OC that may protect the light emitting element layer 130 from foreign substances through the reflection preventing layer ARL and provide a flat surface to the input sensor layer ISL (see FIG. 10G) may be provided.

The overcoat layer OC may be formed through a coating or deposition process. In more detail, the overcoat layer OC may be formed by forming the organic layer by manners such as coating and deposition and then selectively patterning the organic layer by photolithography and etching. In this case, as compared to a case in which the organic layer is formed by an inkjet process, a higher flattening level may be maintained at an edge thereof, and a more decreased thickness may be provided. Accordingly, a distance between the light emitting element ED and the light shielding layer 200-SDL (see FIG. 10G) in the input sensor layer ISL (see FIG. 10G) may be effectively decreased, and a viewing angle may be effectively widened.

As illustrated in FIG. 10G, the method of manufacturing the display panel DP according to an embodiment may include the operation of forming the input sensor layer ISL. The input sensor layer ISL may be directly formed on the reflection preventing layer ARL. That is, the input sensor layer ISL may be directly formed on the overcoat layer OC.

The input sensor layer ISL may include the first sensing insulating layer 200-IL1, the first conductive layer 200-CL1, the second sensing insulating layer 200-IL2, the second conductive layer 200-CL2, and the third sensing insulating layer 200-IL3. The first sensing insulating layer 200-IL1 may be directly disposed on the overcoat layer OC. In an embodiment, the input sensor layer ISL may further include the light shielding layer 200-SDL that is disposed between the second sensing insulating layer 200-IL2 and the third sensing insulating layer 200-IL3 and covers the second conductive layer 200-CL2.

The input sensor layer ISL may be formed through a manufacturing process of forming an insulating layer and a conducive layer by manners such as coating and deposition, selectively patterning the insulating layer and the conductive layer by a photolithography and etching process, and forming a conductive pattern (e.g., a sensing pattern or a bridge pattern having a mesh structure) or the like.

Therefore, the display panel DP including the display layer DPL, the reflection preventing layer ARL, and the input sensor layer ISL may be formed.

According to the present disclosure, as trenches (or overhang structures) are provided near a spacer, even when foreign substances remain in the spacer or the spacer is damaged by scratches on a metal mask, occurrence of defects in light emitting elements may be effectively reduced or prevented. Accordingly, the display device having improved display quality may be provided.

According to the present disclosure, a reflection preventing layer (e.g., a color filter layer) may be directly disposed on a display layer, and thus reflection of an external light caused by electrodes in the display layer may be reduced or prevented. Further, a distance between the display layer and a light shielding layer may be effectively decreased, and a viewing angle may be effectively widened. Accordingly, the display device having improved display quality may be provided.

Although the description has been made above with reference to an embodiment of the present disclosure, it may be understood that those skilled in the art or those having ordinary knowledge in the art may variously modify and change the present disclosure without departing from the spirit and technical scope of the present disclosure described in the appended claims. Thus, the technical scope of the present disclosure is not limited to the detailed description of the specification but should be defined by the appended claims.

What is claimed is:

1. A display device comprising:
an insulating layer in which a first groove and a second groove surrounding the first groove are defined;
a pixel defining layer which is disposed on the insulating layer and in which a light emitting opening, a first spacing opening overlapping the first groove, and a second spacing opening overlapping the second groove and surrounding the first spacing opening are defined;
a light emitting element disposed on the insulating layer and including a first electrode of which at least a portion is exposed by the light emitting opening, a second electrode disposed on the first electrode, and a light emitting layer disposed between the first electrode and the second electrode and overlapping the light emitting opening;
a spacer of which at least a portion is disposed inside the first groove and the first spacing opening;
an inorganic encapsulation film disposed on the second electrode and the spacer; and
a color filter layer directly disposed on the inorganic encapsulation film.

2. The display device of claim 1, wherein a first tip portion of the pixel defining layer protrudes from a first inner surface of the insulating layer defining the first groove in a direction toward a center of the first groove.

3. The display device of claim 2, wherein the spacer is in contact with the first tip portion.

4. The display device of claim 1, wherein the spacer includes:
a first portion disposed inside the first groove and the first spacing opening; and
a second portion extending from the first portion and protruding in a direction away from the first spacing opening.

5. The display device of claim 1, wherein a second tip portion of the pixel defining layer protrudes from a second inner surface of the insulating layer defining the second groove in a direction away from a center of the first groove, and
wherein a third tip portion of the pixel defining layer protrudes from a third inner surface of the insulating layer facing and surrounding the second inner surface and defining the second groove in a direction toward the center of the first groove.

6. The display device of claim 1, wherein the inorganic encapsulation film is in contact with inner surfaces of the pixel defining layer defining the second spacing opening.

7. The display device of claim 1, further comprising:
a dummy pattern disposed in the second groove, spaced apart from the second electrode, and including a same material as the second electrode.

8. The display device of claim 1, wherein the light emitting element is provided in plurality, and the plurality of light emitting elements include a first light emitting element in which a first light emitting area configured to emit a light having a first color is defined, a second light emitting element in which a second light emitting area configured to emit a light having a second color different from the first color is defined, and a third light emitting element in which a third light emitting area configured to emit a light having a third color different from the first color and the second color is defined,
wherein the light emitting opening is provided in plurality, and the plurality of light emitting openings include a first light emitting opening overlapping the first light emitting area, a second light emitting opening overlapping the second light emitting area, and a third light emitting opening overlapping the third light emitting area, and
wherein the color filter layer includes a first color filter of which at least a portion overlaps the first light emitting area, a second color filter of which at least a portion overlaps the second light emitting area, and a third color filter of which at least a portion overlaps the third light emitting area.

9. The display device of claim 8, wherein at least some of the first to third color filters overlap each other in an area which does not overlap any of the first to third light emitting areas.

10. The display device of claim 8, wherein some of the first to third color filters are arranged inside the second groove and the second spacing opening.

11. The display device of claim 1, further comprising:
an overcoat layer configured to cover the color filter layer.

12. The display device of claim 1, further comprising:
an input sensor layer disposed on the color filter layer.

13. The display device of claim 12, wherein the input sensor layer includes:
a first sensing insulating layer disposed on the color filter layer;
a second sensing insulating layer disposed on the first sensing insulating layer;
a third sensing insulating layer disposed on the second sensing insulating layer;
a first conductive layer disposed between the first sensing insulating layer and the second sensing insulating layer;
a second conductive layer disposed between the second sensing insulating layer and the third sensing insulating layer; and
a light shielding layer disposed between the second sensing insulating layer and the third sensing insulating layer and configured to cover the second conductive layer.

14. The display device of claim 1, further comprising:
a sacrificial pattern which is disposed between the first electrode and the pixel defining layer and in which a sacrificial opening overlapping the light emitting opening is defined.

15. The display device of claim 1, wherein the inorganic encapsulation film includes a plurality of layers.

16. The display device of claim 1, wherein a third groove surrounding the second groove is further defined in the insulating layer, and
wherein a third spacing opening overlapping the third groove and surrounding the second spacing opening is further defined in the pixel defining layer.

17. The display device of claim 16, wherein a fourth tip portion of the pixel defining layer protrudes from a fourth inner surface of the insulating layer defining the third groove in a direction away from a center of the first groove, and
wherein a fifth tip portion of the pixel defining film protrudes from a fifth inner surface of the insulating layer facing and surrounding the fourth inner surface and defining the third groove in a direction toward the center of the first groove.

18. The display device of claim 1, further comprising:
a first intermediate insulating layer which is disposed between the insulating layer and the pixel defining layer and in which a (1-1)^{th} lower opening overlapping the first groove and a (1-2)^{th} lower opening overlapping the second groove are defined; and
a second intermediate insulating layer which is disposed between the first intermediate insulating layer and the pixel defining layer and in which a (2-1)^{th} lower opening overlapping the (1-1)^{th} lower opening and a (2-2)^{th} lower opening overlapping the (1-2)^{th} lower opening are defined,
wherein an inner surface of the second intermediate insulating layer defining the (2-1)^{th} lower opening is recessed as compared to the first intermediate insulating layer and the pixel defining layer, and
wherein an inner surface of the second intermediate insulating layer defining the (2-2)^{th} lower opening is recessed as compared to the first intermediate insulating layer and the pixel defining layer.

19. An electronic device comprising:
an insulating layer in which a first groove and a second groove surrounding the first groove are defined;
a pixel defining layer disposed on the insulating layer and including a first tip portion protruding from an inner edge of the insulating layer defining the first groove and second and third tip portions protruding from inner edges of the insulating layer defining the second groove;
a light emitting element disposed on the insulating layer;
a spacer of which at least a portion is disposed inside the first groove;
an inorganic encapsulation film disposed on a second electrode and the spacer; and
a color filter layer directly disposed on the inorganic encapsulation film.

20. The display device of claim 19, wherein the inorganic encapsulation film is in contact with the second and third tip portions.
